(19) United States
(12) Patent Application Publication
(10) Pub. No.: US 2022/0049100 A1
(43) Pub. Date: Feb. 17, 2022

(54) CURABLE SILICONE COMPOSITION FOR TRANSFER MOLDING, CURED PRODUCT THEREOF, AND PRODUCTION METHOD THEREOF

(71) Applicant: DOW TORAY CO., LTD., Shinagawa-ku, Tokyo (JP)

(72) Inventor: Ryosuke YAMAZAKI, Ichihara-Shi, Chiba (JP)

(21) Appl. No.: 17/418,369

(22) PCT Filed: Dec. 27, 2019
(86) PCT No.: PCT/JP2019/051394

§ 371 Date: Sep. 28, 2021

(30) Foreign Application Priority Data
Dec. 27, 2018 (JP) 2018-245661

(51) Int. Cl. C08L 83/04; B29C 45/02; C08G 77/12; C08G 77/20; C08G 77/00; C08G 77/44; C08K 3/22; C08K 3/36; C08K 5/14; C08J 3/12

(52) U.S. Cl. CPC C08L 83/04; C08K 2201/003; C08G 77/12; C08G 77/20; C08G 77/80; C08G 77/44; C08K 3/22; C08K 3/36; C08K 5/14; C08J 3/12; C08L 2205/025; C08L 2205/03; C08L 2203/206; C08K 2003/2241; C08K 2003/2227; C08K 2201/001; B29C 45/02

(57) ABSTRACT

Provided is a curable silicone composition and applications thereof. The curable silicone composition has low modulus and flexibility even at high temperature of a cured product formed therefrom, and superior stress relaxation properties, so that the cured product does not readily warp or become defective when integrally molded with a base material, and has superior demolding property (e.g. mold release) of the cured product after transfer molding. A curable silicone composition for transfer molding, where (1) the maximum torque measured from a molding temperature of room temperature through 200° C. using a moving die rheometer (MDR) is less than 50 dN-m, and (2) the loss tangent (tans) expressed by the ratio of stored torque value/lost torque value is less than 0.2.

### TECHNICAL FIELD

The present invention relates to a curable silicone composition for transfer molding, a molded product (pellet or the like) thereof, and a cured product thereof, which can be obtained by a simple manufacturing method, and in which the molded cured product has low modulus and flexibility even at high temperatures, excellent stress relaxation properties, and excellent transfer moldability and demoldability using the composition. The present invention also relates to a cured product of said composition and applications thereof (in particular, semiconductor components), a method for manufacturing said composition, and a method for molding the cured product.

### BACKGROUND ART

Curable silicone compositions are utilized in a wide range of industrial fields because they are cured to form cured products having excellent heat resistance, cold resistance, electrical insulation, weather resistance, water repellency, and transparency. In general, the cured product of such a curable silicone composition is also suitable as a encapsulant for optical materials and semiconductor devices because it is not readily discolored as compared with other organic materials, and there is less deterioration of physical properties.

The present applicant has proposed, in Patent Document 1 and Patent Document 2, a so-called hot melt curable granular silicone composition and a reactive silicone composition for molding. These silicone compositions are made up of so-called phenyl silicone resins, which have the advantages of superior hot-melt properties and superior hardness and strength of the cured product when compared to methyl silicone resins.

On the other hand, in recent years, optical semiconductor devices have become smaller and higher output, and when these hot-melt curable granular silicone compositions and the like are applied, especially under high temperatures of 200° C. or higher, coloring derived from phenyl silicone resin may occur, and in particular, in the field of reflective materials, light reflectance may decrease. Therefore, there is a strong need for a silicone composition that satisfies the requirements for higher heat resistance and color resistance while achieving hot-melt properties and mechanical strength of the cured product after molding.

Here, in Patent Document 3, a hot-melt curable silicone sheet using a methyl silicone resin is disclosed, but a granular composition is neither described nor suggested in the present invention. Furthermore, organic solvents are indispensable in the mixing process of the compositions in question, and there is no description or suggestion of compositions or granular compositions containing large amounts of functional fillers (especially white pigments) suitable for molding materials. Furthermore, the composition is difficult to use as a composition for molding because the organic solvent must be removed in the process of preparing the sheet, and only a thin sheet can be made to avoid residual solvent. In addition, the fast curing/immediate curing required in the molding process is difficult to achieve because heat is applied in the solvent removal process. Therefore, application of the compositions disclosed in Patent Document 3 to solve the problems described above was difficult.

Furthermore, Patent Document 4 discloses curable silicone pellets for molding using methyl silicone resin, but the production of this composition requires melt mixing at a high temperature, making controlling the curability of the composition difficult and molding over a short period at a low temperature difficult.

On the other hand, in Patent Documents 5 to 7, the Applicants propose that the use of inorganic fillers that do not contain coarse particles in a curable granular silicone composition can improve the toughness and durability, especially at high temperatures, the gap-filling property during melting, and the optical reflectance. In addition, Patent Document 8 proposes a curable silicone composition where combining with a hot melt component such as a stearic acid metal salt provides hot melt properties enables achieving sufficient flowability and gap fill properties while heating and melting, provides superior workability and cured product adhesiveness, and a cured product with superior flexibility and toughness at high temperatures of from room temperature to roughly 150° C.

However, in recent years, with regards to requirements regarding applicability to various semiconductor applications, there is still room for improvement with these curable silicone compositions with regards to their properties. In particular, in transfer molding, there is generally a trade-off between demoldability and stress relaxation properties of the cured product, making it difficult to achieve both of these properties, and the recent miniaturization of mold structures tends to make demoldability more difficult.

In other words, as in Patent Document 4, in a hot-melt silicone composition for molding with a reduced coefficient of linear expansion during transfer molding, the resulting cured product is hard and is prone to warpage and defects due to a slight deviation in the coefficient of linear expansion relative to the base material. On the other hand, when the previously proposed hot-melt curable granular silicone compositions with excellent high temperature softening properties are used for transfer molding, the cured products have flexible properties at high temperatures and separation from the mold after curing is difficult, and may not be sufficiently demoldable from molds with a miniature structure. Therefore, there is a strong need for a curable silicone composition that has excellent stress relaxation properties of the cured product, does not cause warpage or defects, and has excellent demolding properties.

On the other hand, the Applicant has proposed a thermosetting film-type silicone encapsulant for encapsulating semiconductor devices using compression molding, where the initial torque value measured using MDR at molding temperatures from room temperature to 200° C. is less than 15 dN-m (Patent Document 9). This encapsulant has superior moldability for the purpose of encapsulating semiconductors such as LEDs and is useful in that it does not have problems such as overflow from a mold and does not have defects such as voids but still has room for improvement in performance regarding demoldability during transfer molding and stress relaxation properties of the cured product, in particular in not having achieved optimization of preventing warpage of the molded product and demoldability.

### PRIOR ART D0CUMENTS

### Patent Documents

Patent Document 1: International Unexamined Patent Application 2016/136243
Patent Document 2: Japanese Unexamined Patent Application 2014-009322
Patent Document 3: Japanese Unexamined Patent Application Publication (Translation of PCT Application) No. 2017-512224
Patent Document 4: Japanese Unexamined Patent Application 2009-155415
Patent Document 5: International Unexamined Patent Application 2018/030286
Patent Document 6: International Unexamined Patent Application 2018/030287
Patent Document 7: International Unexamined Patent Application 2018/030288
Patent Document 8: International Patent Application PCT/JP2018/19574
Patent Document 9: Japanese Unexamined Patent Application Publication No. 2013-232580

### SUMMARY OF THE INVENTION

### Problems to be Solved by the Invention

An object of the present invention is to provide a cured silicone composition having superior workability and curing characteristics in transfer molding, low modulus and flexibility even at high temperature of the molded cured product, and superior stress relaxation properties so that the molded product does not readily warp or become defective when integrally molded with a base material, and has superior demolding properties of the cured product after transfer molding. Furthermore, an object of the present invention is to provide molded products (including, in particular, pellets) using the curable silicone composition as well as cured product thereof. An additional object of the present invention is to provide a cured product of the composition as well as applications thereof (including, in particular, a member for semiconductors and a power semiconductor having the cured product, and the like), a method for manufacturing the composition and a method for molding the cured product, and the like.

### Means for Solving the Problems

As a result of intensive investigation, the inventors have developed a curable silicone composition for transfer molding in which (1) the maximum torque value measured by Moving Die Rheometer (MDR) at molding temperatures from room temperature to 200° C. is less than 50 dN-m, and (2) when the maximum torque value is reached, the loss tangent (tanδ) expressed as the ratio of the stored torque value/lost torque value is less than 0.2, and in particular, the curable silicone composition for transfer molding includes (A) a curable reactive organopolysiloxane, (B) a functional filler, and (C) a curing agent, where 50 mass % or more of component (A) is made up of (A1) an organopolysiloxane having a curable reactive functional group containing at least one carbon-carbon double bond in the molecule, where siloxane units selected from the siloxane units represented by RSiO_{3/2} (in the formula, R is a monovalent organic group) and the siloxane units represented by SiO_{4/2} make up 20 mol % or more of the total siloxane units and the content of component (B) is 40% or less of the entire composition and thus resolving the problem described above using the curable silicone composition for transfer molding. Here, the curable silicone composition for transfer molding described above may be in the form of a paste, but the composition as a whole is preferably hot-meltable. The curable silicone composition described above is preferably in pellet form.

Furthermore, the present inventors have found that the cured product of the transfer-molding curable silicone composition, in particular, the use of the cured product as a member for semiconductor devices, and semiconductor devices having the cured product (including one or more types selected from power semiconductor devices, optical semiconductor devices, and semiconductor devices mounted on flexible circuit boards) can solve the problem described above, thus arriving at the present invention.

Similarly, the inventors have found that the above problem can be solved by a manufacturing method characterized in that only specific components constituting the curable silicone composition described above are granulated by mixing them under temperature conditions not exceeding 50° C., and a molding method of a cured product using the above curable granular silicone composition.

Note, the curable silicone composition of the present invention has excellent moldability and demoldability, and is suitable as a material for transfer molding. Furthermore, the curable silicone composition of the present invention can be suitably used as a molding material in a so-called overmold method, which is a step of coating a semiconductor element or a semiconductor circuit board with the cured product by overmold molding.

### Effects of the Invention

The cured silicone composition for transfer molding of the present invention has superior workability and curing characteristics in transfer molding, and the molded cured product has excellent low modulus and flexibility at high temperatures, excellent stress relaxation properties, does not readily exhibit warpage of the molded product or defects when integrally molded with a base material, and has superior cured product demoldability after molding. In addition, such a curable silicone composition for transfer molding can be produced using only simple mixing processes and can be efficiently manufactured. Furthermore, the present invention provides molded articles (including in particular pellets) and cured product thereof using the cured silicone composition for transfer molding described above. Furthermore, the present invention can provide a member for a semiconductor device comprising a cured product of the composition described above, a semiconductor device having the cured product, and a method for molding the cured product.

### Mode for Carrying out the Invention

### [Curing Behavior of Curing Silicone Composition for Transfer Molding]

The cured silicone composition of the present invention is a cured silicone composition for transfer molding, and the composition as a whole may be in the form of a paste or a molded product such as a hot-melt pellet or the like. In order to achieve both demoldability in transfer molding and stress relaxation properties of the cured product, which are essentially in a trade-off relationship, this type of composition must have (1) a maximum torque value of less than 50 dN-m as measured by MDR (Moving Die Rheometer) at molding temperatures from room temperature to 200° C. and (2) when the maximum torque value is reached, the loss tangent (tanδ) value, which is expressed as the ratio of the stored torque value/lost torque value, must be less than 0.2. In particular, (1) the maximum torque value measured by the MDR set at 150° C., which is a general molding temperature, is in particular preferably less than 50 dN-m, and (2) when the maximum torque value is reached, the value of the loss tangent (tanδ) expressed as the ratio of the stored torque value/lost torque value is particularly preferably less than 0.2. Note, it goes without saying that as long as the curing behavior described above is satisfied and the physical properties of the MDR at a specific temperature (for example, 150° C.) are satisfied, the cured silicone composition for transfer molding of the present invention can be selected and used for any desired molding temperature from room temperature to 200° C. (for example, a molding temperature other than 150° C.).

The maximum torque values and described above are explained below. In the present invention, the torque value is the torque value obtained by measurement of the cured product consisting of the cured composition by MDR in accordance with JIS K 6300-2 “Physical properties of unvulcanized rubber—Part 2: Determination of vulcanization characteristics by vibratory vulcanization tester.” The maximum torque value is the maximum torque value measured during 600 seconds after vulcanization at the molding temperature, preferably 150° C. Here, the maximum torque value of the cured product at the molding temperature of the cured product being less than 50 dN-m means that the cured product after molding is soft even at a high temperature, that is, the cured product has a low modulus and is flexible, a low elastic modulus, and superior stress relaxation properties. In the present invention, the maximum torque value of the cured product at the molding temperature may be less than 40 dN-m, preferably less than 35 dN-m, and particularly preferably in the range of 5 to 30 dN-m. In this range, both sufficient stress relaxation properties of the cured product can be achieved and the loss tangent (tanδ) described below can be achieved. On the other hand, if the maximum torque value at the molding temperature of the cured product exceeds the upper limit described above, the cured product is excessively hard and stress relaxation properties cannot be achieved, and this may cause warpage or defects in the molded material, especially when integrally molded with the base material.

Next, the conditions for the loss tangent (tanδ) of the composition in the present invention will be described. The loss tangent (tanδ) is measured through measurement using MDR as described above by reading the value of the loss tangent (tanδ), which is expressed as the ratio of the stored torque value/lost torque value, when the maximum torque value is reached. Here, the loss tangent (tanδ) of the composition being less than 0.2 means that the rubber elasticity of the cured product resulting from curing the composition is low, the surface thereof is moderately hard, and the cured product does not readily adhere to/attach onto the metal mold when being released from the mold in the molding process and has superior demoldability. From the viewpoint of demoldability, the loss tangent (tanδ) of the cured product is preferably in the range of 0.01 to 0.19 when the maximum torque value is reached, and the loss tangent is particularly preferably in the range of 0.03 to 0.18. On the other hand, if the loss tangent (tanδ) of the composition exceeds 0.2, the rubber elasticity of the obtained cured product becomes high and the surface thereof becomes sticky, so that the cured product tends to adhere to/attach to the metal mold when being released from the mold, and smooth separation from the metal mold does not readily occur, and demoldability may become insufficient.

In the cured product, by satisfying both (1) the condition of the maximum torque value and (2) the condition of the loss tangent (tanδ) value expressed as the ratio of the stored torque value/lost torque value when the maximum torque value is reached, the cured silicone composition for transfer molding of the present invention has superior stress relaxation properties of the cured product and is resistant to warpage and defects in the cured product, and achieves favorable demolding properties.

### [Composition of Curable Silicone Composition for Transfer Molding]

The curable silicone composition for transfer molding of the present invention further comprises:
(A) a curable reactive organopolysiloxane;
(B) a functional filler; and
(C) a curing agent,
and it is particularly preferred that 50 mass % or more of component (A) is an organopolysiloxane having (A1) a curing-reactive functional group containing at least one carbon-carbon double bond in the molecule with siloxane units making up 20 mol % or more of the total siloxane units selected from siloxane units represented by RSiO_{3/2} (in the formula, R is a monovalent organic group) and siloxane units represented by SiO_{4/2}, and the content of component (B) is 40 volume % or less of the entire composition. The content of component (A1) is preferably in the range of 20 to 80 mass % of the entire composition. Hereinafter, each component and optional component of the composition will be described. In the present invention, the term “average particle diameter” means the primary average particle diameter of the particles unless otherwise defined.

[Component (A), Mainly Containing Component (A1)]

Component (A) is one of the main agents of the composition and is one or more curable reactive organopolysiloxane having a curing-reactive group in the molecule, at least 50 mass % of which is siloxane units making up at least 20 mol % of the total siloxane units selected from siloxane units represented by
(A1) RSiO_{3/2} (in the formula, R is a monovalent organic group) and siloxane units represented by SiO_{4/2}, and the organopolysiloxane has a curing-reactive functional group containing a carbon-carbon double bond in the molecule. Component (A) may include only one or more components (A1), or it may be a mixture including a curable reactive organopolysiloxane other than component (A1).

The composition preferably contains component (A1) in the range of 20 to 80 mass % of the entire composition, and more preferably in the range of 30 to 75 mass %. This type of component (A1) is preferably waxy or solid at room temperature, and may be used as a viscous liquid by dissolving it in a liquid component (A) at room temperature other than component (A1) when producing a paste-like composition. When producing a hot-melt composition, the composition is preferably used alone or together with other components (for example, some of components (C) which are curing agents) in the form of microparticles, and it is particularly preferable to use spherical silicone microparticles having an average primary particle diameter of 1 to 20 μm.

Component (A1) must have a curing reactive group having a carbon-carbon double bond in the molecule. This type of a curing-reactive group being hydrosilylation reactive or an organic peroxide curing functional group that forms a cured product based on a crosslinking reaction with other components. Such a curing-reactive group is an alkenyl group or an acrylic group, and examples thereof include alkenyl groups having from 2 to 10 carbon atoms such as vinyl groups, allyl groups, butenyl groups, pentenyl groups, hexenyl groups, and heptenyl groups; and acrylic group-containing monovalent organic groups such as 3-methacryloxypropyl groups and 3-acryloxypropyl groups. Vinyl groups or hexenyl groups are particularly preferable.

Examples of the group bonded to a silicon atom other than the hydrosilylation reactive group in component (A1) include an alkyl group having 1 to 20 carbon atoms, a halogen-substituted alkyl group having 1 to 20 carbon atoms, an aryl group having 6 to 20 carbon atoms, a halogen-substituted aryl group having 6 to 20 carbon atoms, an aralkyl group having 7 to 20 carbon atoms, an alkoxy group, and a hydroxyl group. Specific examples thereof include alkyl groups such as methyl, ethyl, propyl, butyl, pentyl, hexyl, heptyl, octyl, nonyl, decyl, undecyl, and dodecyl; aryl groups such as phenyl, tolyl, xylyl, naphthyl, anthracenyl, phenanthryl, and pyrenyl; aralkyl groups such as phenethyl and phenylpropyl; groups in which a part or all of the hydrogen atoms bonded to these groups are substituted with a halogen atom such as a chlorine atom and a bromine atom; and alkoxy groups such as methoxy, ethoxy, and propoxy. In particular, a phenyl group and a hydroxyl group are preferable. In particular, in component (A1), it is preferable that 10 mol % or more of the total organic groups in the molecule be an aryl group, in particular, a phenyl group.

Component (A1) is the main component that determines the curing behavior of this composition. The composition of the present invention has (1) a maximum torque value of less than 50 dN-m as measured by MDR (Moving Die Rheometer) at molding temperatures from room temperature to 200° C., and (2) a loss tangent (tanδ) value expressed as the ratio of the stored torque value/lost torque value when the maximum torque value is reached of less than 0.2. The glass transition temperature of component (A1) is preferably less than or equal to the molding temperature described above to set the maximum torque value to less than 50 dN-m. In order for the value of the aforementioned tanδ at the molding temperature to be less than 0.2, the glass transition temperature of component (A1) should be some distance away from the molding temperature. However, if the glass transition point is far below room temperature, the strength of the obtained cured product at room temperature tends to be low, and therefore, essentially, the glass transition point of component (A1) is preferably in the range of room temperature to molding temperature, and more preferably in the range of room temperature to 100° C. From the viewpoint that the strength at room temperature of the resulting cured product is improved, the glass transition temperature is preferably above room temperature. That is, component (A1) is preferably hot-meltable. Specifically, component (A1) should be non-flowable at 25° C. and have a melt viscosity at 100° C. of 8,000 Pa-s or less. Non-fluid refers to not flowing in a no-load condition, for example, the state of being lower than the softening point measured by the softening point testing method in the ball and ring method of hot melt adhesives specified in “Testing methods for the softening point of hot melt adhesives” of JIS K 6863-1994. That is, in order to be non-fluid at 25° C., the softening point must be higher than 25° C.

Component (A1) preferably has a melt viscosity at 100° C. of 8,000 Pa·s or less, 5,000 Pa·s or less, or within the range of 10 to 3,000 Pa·s. Moreover, when the melt viscosity at 100° C. is within the abovementioned range, favorable adhesiveness after being hot melted and then cooled at 25° C. is obtained.

If imparting hot-melt properties to the composition of the present invention is desirable, component (A1), and the entire (A) component that includes the component (A1)], are preferably in particulate form. The particle diameter thereof is not restricted, but the average primary particle diameter is preferably within the range of 1 to 5,000 μm, within the range of 1 to 500 μm, within the range of 1 to 100 μm, within the range of 1 to 20 μm, or within the range of 1 to 10 μm. The average primary particle diameter can be obtained, for example, by observation with an optical microscope or an SEM. The shape of component (A1) or component (A) overall is not restricted, and a spherical shape, a spindle shape, a plate shape, a needle shape, and an irregular shape are exemplified, and it is preferable to have a spherical shape or a true spherical shape because it melts uniformly. In particular, by making the entire component (A) a spherical shape of 1 to 10 μm, the melting properties and the mechanical properties after curing of this compound can be favorably improved.

Component (A1) is any one of the following:
(A₁) a resinous organopolysiloxane;
(A₂) an organopolysiloxane crosslinked product obtained by crosslinking at least one type of organopolysiloxane;
(A₃) a block copolymer composed of a resinous organosiloxane block and a chained organosiloxane block; or a mixture of at least two of these,
preferably made up of silicone microparticles.

Component (A₁) is a resinous organopolysiloxane having a hydrosilylation reactive group and/or a radical reactive group, and is preferably a hot-melt resinous organopolysiloxane having a large number of T-units or Q-units and an aryl group. Examples of such a component (A₁) include MQ resins, MDQ resins, MTQ resins, MDTQ resins, TD resins, TQ resins, and TDQ resins consisting of any combination of: a triorganosiloxane unit (M unit) (the organo group is a methyl group only, a methyl group and a vinyl group, or a phenyl group); a diorganosiloxane unit (D unit) (the organo group is a methyl group only, a methyl group and a vinyl group, or a phenyl group); a monoorganosiloxane unit (T unit) (the organo group is a methyl group, a vinyl group, or a phenyl group); and a siloxy unit (Q unit). It is preferable that component (Ai) has at least two hydrosilylation reactive groups and/or radical reactive groups in the molecule, and 10 mol % or more of the total organic groups in the molecule is an aryl group, particularly, a phenyl group.

In addition, since component (A₂) is formed by crosslinking at least one organopolysiloxane, cracks are hardly generated when the component is cured by the curing agent (C), and the curing shrinkage can be reduced. Here, “crosslinking” means linking the organopolysiloxane as a raw material by a hydrosilylation reaction, a condensation reaction, a radical reaction, a high energy ray reaction, or the like. Examples of the hydrosilylation reactive group and the radical reactive group (including the high energy ray reactive group) include the same groups as those described above, and examples of the condensation reactive group include a hydroxyl group, an alkoxy group, and an acyloxy group.

The unit constituting component (A₂) is not limited, and siloxane units and siloxane units containing silalkylene groups are exemplified, and it is preferable to have a resinous polysiloxane unit and a chained polysiloxane unit in the same molecule because they impart adequate hardness and mechanical strength to the obtained cured product. That is, component (A₂) is preferably a crosslinked product of a resinous organopolysiloxane and a chained organopolysiloxane (including a linear or branched chain organopolysiloxane). By introducing the resinous organopolysiloxane structure-chained organopolysiloxane structure into component (A₂), component (A₂) exhibits good hot-melt properties, and the curing agent (C) exhibits good curing properties.

Component (A2) is any one of the following (1) to (3):
(1) One obtained by linking a resinous organopolysiloxane structure-chain organopolysiloxane structure in the molecule by an alkylene linkage via a hydrosilylation reaction of an organopolysiloxane having at least two alkenyl groups in one molecule and an organopolysiloxane having at least two silicon atom bonded hydrogen atoms in one molecule;
(2) One obtained by linking a resinous organopolysiloxane structure-chain organopolysiloxane structure in the molecule by a siloxane linkage or an alkylene linkage via a radical reaction of an organic peroxide of at least two organopolysiloxanes having at least two radical reactive groups in one molecule;
(3) One obtained by linking a resinous organopolysiloxane structure-chain organopolysiloxane structure in the molecule by a siloxane (—Si—O—Si—) linkage via a condensation reaction of at least two organopolysiloxanes. Such component (A₂) has a structure in which organopolysiloxane moieties of the resin structure-chain structure are linked by an alkylene group or new siloxane linkage, so that hot-melt properties are remarkably improved.

In the above (1) and (2), as the alkylene group contained in component (A₂), an alkenyl group having 2 to 20 carbon atoms such as an ethylene group, a propylene group, a butylene group, a pentylene group, a hexylene group, or the like is exemplified, and these groups may be linear or branched, and are preferably an ethylene group or a hexylene group.

The crosslinked products of resinous organopolysiloxanes and chain organopolysiloxanes, including linear or branched chain organopolysiloxanes, are composed of, for example, the following siloxane units and siloxane units containing silalkylene groups:
M-units: siloxane units represented by R¹R²₂SiO_{1/2};
D-units: siloxane units represented by R¹R²SiO_{2/2};
R³M/R³D-units: at least one siloxane unit selected from a silalkylene group containing siloxane unit represented by R³_{1/2}R²₂SiO_{1/2} and a silalkylene group containing siloxane unit represented by R³_{1/2}R²SiO_{2/2}; and
T/Q-units: at least one siloxane unit selected from a siloxane unit represented by R²SiO_{3/2} and a siloxane unit represented by SiO_{4/2}.

In the formula, each R¹ is independently an alkyl group having 1 to 20 carbon atoms, a halogen-substituted alkyl group having 1 to 20 carbon atoms, an alkenyl group having 2 to 20 carbon atoms, an aryl group having 6 to 20 carbon atoms, a halogen-substituted aryl group having 6 to 20 carbon atoms, or an aralkyl group having 7 to 20 carbon atoms, and the same groups as described above are exemplified. R¹ is preferably a methyl group, a vinyl group, or a phenyl group. However, it is preferable that at least two R¹ of all siloxane units are alkenyl groups.

In addition, in the formula, each R² is independently an alkyl group having 1 to 20 carbon atoms, a halogen-substituted alkyl group having 1 to 20 carbon atoms, an aryl group having 6 to 20 carbon atoms, a halogen-substituted aryl group having 6 to 20 carbon atoms, or an aralkyl group having 7 to 20 carbon atoms, and the same groups as the R¹ are exemplified. R² is preferably a methyl group or a phenyl group.

In the formulae, R³ is a linear or branched alkylene group having 2 to 20 carbon atoms bonded to a silicon atom in other siloxane units. As the alkylene group, the same groups as described above are exemplified, and an ethylene group and a hexylene group are preferable.

The M-unit is a siloxane unit constituting the terminal of component (A₂), and the D-unit is a siloxane unit constituting a linear polysiloxane structure. Note that it is preferable that an alkenyl group is present on the M-unit or the D-unit, in particular, the M-unit. On the other hand, the R³M-unit and the R³D-unit are siloxane units bonded to a silicon atom in another siloxane unit via a silalkylene linkage and bonded to a silicon atom in another siloxane unit via an oxygen atom. The T/Q-unit is a branched siloxane unit which gives a resinous structure to the polysiloxane, and component (A₂) preferably contains a siloxane unit represented by R²SiO_{3/2} and/or a siloxane unit represented by SiO_{4/2}. In particular, since the hot-melt properties of component (A₂) are improved and the content of the aryl group in component (A₂) is adjusted, it is preferable that component (A₂) contains a siloxane unit represented by R²SiO_{3/2}, and in particular, it is preferable that component (A₂) contains a siloxane unit in which R² is a phenyl group.

The R³M/R³D-unit is one of the characteristic structures of component (A₂), and represents a structure in which silicon atoms are crosslinked via the alkylene group of R³. Specifically, the R³M/R³D-unit is at least one siloxane unit selected from an alkylene group-containing siloxane unit represented by R³_{1/2}R²₂SiO_{1/2} and an alkylene group-containing siloxane unit represented by R³_{1/2}R²SiO_{2/2}, and at least two of all siloxane units constituting component (A₂) are preferably these alkylene group-containing siloxane units. The preferred form of linkage between siloxane units having alkylene groups of R³ is as described above, and the number of R³ between two alkylene group-containing siloxane units is expressed as the linkage number “½” as is the number of oxygens and the like in the M-units. Assuming that the number of R³ is 1, at least one selected from the structural units of siloxanes represented by [O_{1/2}R²₂SiR³SiR²₂O_{1/2}], [O_{1/2}R²₂SiR³SiR²O_{2/2}], and [O_{2/2}R²SiR³SiR²O_{2/2}] is contained in component (A₂), and each oxygen atom (O) is bonded to a silicon atom contained in the M, D, and T/Q-units. With such a structure, component (A₂) can relatively easily design a structure having a chain polysiloxane structure comprised of D-units and a resinous polysiloxane structure containing T/Q-units in the molecule, and the component is remarkably excellent in physical properties.

In the above (1), the component can be obtained by hydrosilylation reaction of an organopolysiloxane having at least two alkenyl groups in one molecule and an organopolysiloxane having at least two silicon atom bonded hydrogen atoms in one molecule at a reaction ratio of [number of moles of alkenyl groups]/[number of moles of silicon atom bonded hydrogen atoms]>1.

In the above (2), the component can be obtained by radical reaction of at least two organopolysiloxanes having at least two radical reactive groups in one molecule with an organic peroxide in an amount which is insufficient for all radical reactive groups in the system to react.

In the above (1) and (2), component (A₂) is obtained by subjecting an organopolysiloxane having a resinous siloxane structure and an organopolysiloxane having a chain siloxane structure to a hydrosilylation reaction or a radical reaction.

For example, component (A₂) is an organopolysiloxane obtained by reacting: (A^{R}) at least one type of resinous organopolysiloxane containing a siloxane unit represented by R²SiO_{3/2} (where R² is the same group as described above) and/or a siloxane unit represented by SiO_{4/2} in the molecule and having an alkenyl group with 2 to 20 carbon atoms or a silicon-bonded hydrogen atom or a radical reactive group; and (A^{L}) at least one type of chained organopolysiloxane (A^{L}) containing a siloxane unit represented by R²₂SiO_{2/2} (where R² is the same group as described above) in the molecule and having a group capable of a hydrosilylation reaction or a radical reaction with the component (A^{R}), the group being an alkenyl group with 2 to 20 carbon atoms or a silicon-bonded hydrogen atom; at a ratio designed so that the hydrosilylation reactive group and/or radical reactive group in component (A^{R}) or component (A^{L}) remains after the reaction.

In the above (1), when at least a part of component (A^{R}) is a resinous organopolysiloxane having an alkenyl group of 2 to 20 carbon atoms, it is preferable that at least a part of component (A^{L}) is a chain organopolysiloxane having a silicon atom bonded hydrogen atom.

Similarly, when at least a part of component (A^{R}) is a resinous organopolysiloxane having a silicon atom bonded hydrogen atom, it is preferable that at least a part of component (A^{L}) is a chain organopolysiloxane having an alkenyl group of 2 to 20 carbon atoms.

Such a component (A₂) is preferably:
component (a₁): a substance obtained by performing a radical reaction on an organopolysiloxane having at least two alkenyl groups with 2 to 20 carbon atoms in the molecule containing the component (a₁₋₁) below and/or the component (a₁₋₂) below, with an organic peroxide; or
a substance obtained by performing a hydrosilylation reaction on component (a₁) and (a₂) an organohydrogenpolysiloxane
in the presence of a hydrosilylation reaction catalyst in an amount such that the molar ratio of the silicon-bonded hydrogen atoms in the component (a₂) is from 0.2 to 0.7 mol with respect to the alkenyl groups having 2 to 20 carbon atoms included in the component (a₁).

Component (a₁₋₁) is polysiloxanes with relatively large amounts of branching units, and organopolysiloxanes having at least two alkenyl groups in one molecule, expressed by the average unit formula:

(R⁴₃SiO_{1/2})ₐ(R⁴₂SiO_{2/2})_{b}(R⁴SiO_{3/2})_{c}(SiO_{4/2})_{d}(R⁴O_{1/2})ₑ

In the formula, each R⁴ is independently an alkyl group having 1 to 20 carbon atoms, a halogen-substituted alkyl group having 1 to 20 carbon atoms, an alkenyl group having 2 to 20 carbon atoms, an aryl group having 6 to 20 carbon atoms, a halogen-substituted aryl group having 6 to 20 carbon atoms, or an aralkyl group having 7 to 20 carbon atoms, and the same groups as the R¹ are exemplified. Preferably, R⁴ is a methyl group, a vinyl group, or a phenyl group. Note that at least two of R⁴ are alkenyl groups. In addition, since the hot-melt properties are good, it is preferable that 10 mol % or more, or 20 mol % or more of the total R4 is a phenyl group. Furthermore, in the formula, R⁵ is a hydrogen atom or an alkyl group having 1 to 6 carbon atoms, and the same alkyl groups as those described above are exemplified.

In the formula, a is a number within the range of 0 to 0.7, b is a number within the range of 0 to 0.7, c is a number within the range of 0 to 0.9, d is a number within the range of 0 to 0.7, e is a number within the range of 0 to 0.1, and c+d is a number within the range of 0.3 to 0.9, a+b+c+d is 1, preferably a is a number within the range of 0 to 0.6, b is a number within the range of 0 to 0.6, c is a number within the range of 0 to 0.9, d is a number within the range of 0 to 0.5, e is a number within the range of 0 to 0.05, and c+d is a number within the range of 0.4 to 0.9, a+b+c+d is 1. This is because the hardness and mechanical strength of the obtained cured product are excellent when a, b, and c+d are each a number within the above range.

As such a component (a₁₋₁), the following organopolysiloxanes are exemplified. In the formula, Me, Ph, and Vi represent a methyl group, a phenyl group, and a vinyl group, respectively.

(ViMe₂SiO_{1/2})_{0.25}(PhSiO_{3/2})_{0.75}(HO_{1/2})_{0.02}

(ViMe₂SiO_{1/2})_{0.25}(PhSiO_{3/2})_{0.75}

(ViMe₂SiO_{1/2})_{0.20}(PhSiO_{3/2})_{0.80}

(ViMe₂SiO_{1/2})_{0.15}(Me₃SiO_{1/2})_{0.38}(SiO_{4/2})_{0.47}(HO_{1/2})_{0.01}

(ViMe₂SiO_{1/2})_{0.13}(Me₃SiO_{1/2})_{0.45}(SiO_{4/2})_{0.42}(HO_{1/2})_{0.01}

(ViMe₂SiO_{1/2})_{0.15}(PhSiO_{3/2})_{0.85}(HO_{1/2})_{0.01}

(Me₂SiO_{2/2})_{0.15}(MeViSiO_{2/2})_{0.10}(PhSiO_{3/2})_{0.75}(HO_{1/2})_{0.04}

(MeViPhSiO_{1/2})_{0.20}(PhSiO_{3/2})_{0.80}(HO_{1/2})_{0.05}

(ViMe₂SiO_{1/2})_{0.15}(PhSiO_{3/2})_{0.75}(SiO_{4/2})_{0.10}(HO_{1/2})_{0.02}

(Ph₂SiO_{2/2})_{0.25}(MeViSiO_{2/2})_{0.30}(PhSiO_{3/2})_{0.45}(HO_{1/2})_{0.04}

(Me₃SiO_{1/2})_{0.20}(ViMePhSiO_{1/2})_{0.40}(SiO_{4/2})_{0.40}(HO_{1/2})_{0.08}

Component (a₁₋₂) is polysiloxanes with relatively large amounts of chain siloxane units, and organopolysiloxanes having at least two alkenyl groups in one molecule, expressed by the average unit formula:

(R⁴₃SiO_{1/2})ₐ′(R⁴₂SiO_{2/2})_{b}′(R⁴SiO_{3/2})_{c}′(SiO_{4/2})_{d}′(R⁵O_{1/2})ₑ′

In the formula, R⁴ and R⁵ are the same groups as described above.

In the formula, a′ is a number within the range of 0.01 to 0.3, b′ is a number within the range of 0.4 to 0.99, c′ is a number within the range of 0 to 0.2, d′ is a number within the range of 0 to 0.2, e′ is a number within the range of 0 to 0.1, and c′+d′ is a number within the range of 0 to 0.2, a′+b′+c′+d′ is 1, preferably a′ is a number within the range of 0.02 to 0.20, b′ is a number within the range of 0.6 to 0.99, c′ is a number within the range of 0 to 0.1, d′ is a number within the range of 0 to 0.1, j′ is a number within the range of 0 to 0.05, and c′+d′ is a number within the range of 0 to 0.1, a′+b′+c′+d′ is 1. This is because if a′, b′, c′, and d′ are each a number within the above range, the obtained cured product can be imparted with toughness.

As such a component (a₁₋₂), the following organopolysiloxanes are exemplified. In the formula, Me, Ph, and Vi represent a methyl group, a phenyl group, and a vinyl group, respectively.

ViMe₂SiO(MePhSiO)₁₈SiMe₂Vi, i.e., (ViMe₂SiO_{1/2})_{0.10}(MePhSiO_{2/2})_{0.90}

ViMe₂SiO(MePhSiO)₃₀SiMe₂Vi, in other words, (ViMe₂SiO_{1/2})_{0.063}(MePhSiO_{2/2})_{0.937}

ViMe₂SiO(MePhSiO)₁₅₀SiMe₂Vi, in other words, (ViMe₂SiO_{1/2})_{0.013}(MePhSiO_{2/2})_{0.987}

ViMe₂SiO(Me₂SiO)₁₈SiMe₂Vi, i.e., (ViMe₂SiO_{1/2})_{0.10}(Me₂SiO_{2/2})_{0.90}

ViMe₂SiO(Me₂SiO)₃₀SiMe₂Vi, in other words, (ViMe₂SiO_{1/2})_{0.063}(Me₂SiO_{2/2})_{0.937}

ViMe₂SiO(Me₂SiO)₃₅(MePhSiO)₁₃SiMe₂Vi, i.e.,

(ViMe₂SiO_{1/2})_{0.04}(Me₂SiO_{2/2})_{0.70}(MePhSiO_{2/2})_{0.26}

ViMe₂SiO(Me₂SiO)₁₀SiMe₂Vi, in other words, (ViMe₂SiO_{1/2})_{0.17}(Me₂SiO_{2/2})_{0.83}

(ViMe₂Sio_{1/2})_{0.10}(MePhSiO_{2/2})_{0.80}(PhSiO_{3/2})_{0.10}(HO_{1/2})_{0.02}

(ViMe₂SiO_{1/2})_{0.20}(MePhSiO_{2/2})_{0.70}(SiO_{4/2})_{0.10}(HO_{1/2})_{0.01}

HOMe₂SiO(MeViSiO)₂₀SiMe₂OH

Me₂ViSiO(MePhSiO)₃₀SiMe₂Vi

Me₂ViSiO(Me₂SiO)₁₅₀SiMe₂Vi

Component (a₁₋₁) is preferably used from the viewpoint of imparting hardness and mechanical strength to the obtained cured product. Component (a₁₋₂) can be added as an optional component from the viewpoint of imparting toughness to the obtained cured product, but when a crosslinking agent having many chained siloxane units is used in the following component (a₂), it may be used instead. In any case, it is preferable that the mass ratio of the component having a large number of branched siloxane units to the component having a large number of chained siloxane units is within the range of 50:50 to 100:0, or within the range of 60:40 to 100:0. This is because the hardness and mechanical strength of the obtained cured product are good when the mass ratio of the component having a large number of branched siloxane units to the component having a large number of chained siloxane units is within the above range.

When component (a₁) is radically reacted by an organic peroxide, component (a₁₋₁) and component (a₁₋₂) may be reacted within the range of 10:90 to 90:10, and component (a₂) may not be used.

Component (a₂) is a component for crosslinking component (a₁₋₁) and/or component (a₁₋₂) in the hydrosilylation reaction, and is an organopolysiloxane containing at least two silicon atom bonded hydrogen atoms in one molecule. As a group bonded to a silicon atom other than a hydrogen atom in component (a₂), an alkyl group having 1 to 20 carbon atoms, a halogen-substituted alkyl group having 1 to 20 carbon atoms, an aryl group having 6 to 20 carbon atoms, a halogen-substituted aryl group having 6 to 20 carbon atoms, an aralkyl group having 7 to 20 carbon atoms, an alkoxy group, an epoxy group-containing group, or a hydroxyl group is exemplified, and the same groups as those described above are exemplified.

Such component (a₂) is not limited, but preferably is an organohydrogenpolysiloxane, represented by the average composition formula:

R⁶ₖHₘSiO_{(4-k-m)/2}

In the formulae, R⁶ is an alkyl group having 1 to 20 carbon atoms, a halogen-substituted alkyl group having 1 to 20 carbon atoms, an aryl group having 6 to 20 carbon atoms, a halogen-substituted aryl group having 6 to 20 carbon atoms, or an aralkyl group having 7 to 20 carbon atoms, and the same groups as the above R¹ are exemplified, and preferably a methyl group or a phenyl group.

In the formula, k is a number in the range of 1.0 to 2.5, preferably in the range of 1.2 to 2.3, m is a number in the range of 0.01 to 0.9, preferably in the range of 0.05 to 0.8, and k+m is a number in the range of 1.5 to 3.0, preferably in the range of 2.0 to 2.7.

Component (a₂) may be a resinous organohydrogenpolysiloxane having a large number of branched siloxane units, or the component may be a chained organohydrogenpolysiloxane having a large number of chained siloxane units. Specifically, examples of component (a₂) include an organohydrogenpolysiloxane represented by the following (a₂₋₁), an organohydrogenpolysiloxane represented by the following (a₂₋₂), or mixtures thereof.

Component (a₂₋₁) is an organopolysiloxane having at least two silicon atom bonded hydrogen atoms in one molecule, expressed by the average unit formula:

[R⁷₃SiO_{1/2}]_{f}[R⁷₂SiO_{2/2}]_{g}[R⁷SiO_{3/2}]ₕ[SiO_{4/2}]ᵢ(R⁵O_{1/2})ⱼ

In the formula, each R⁷ is independently an alkyl group having 1 to 20 carbon atoms, a halogen-substituted alkyl group having 1 to 20 carbon atoms, an aryl group having 6 to 20 carbon atoms, a halogen-substituted aryl group having 6 to 20 carbon atoms, an aralkyl group having 7 to 20 carbon atoms, or a hydrogen atom, and the same groups as the above R¹ are exemplified. Furthermore, in the formula, R⁵ represents a hydrogen atom or an alkyl group having 1 to 6 carbon atoms, and the same groups as described above are exemplified.

In the formula, f is a number within the range of 0 to 0.7, g is a number within the range of 0 to 0.7, h is a number within the range of 0 to 0.9, i is a number within the range of 0 to 0.7, j is a number within the range of 0 to 0.1, and h+i is a number within the range of 0.3 to 0.9, f+g+h+i is 1, preferably f is a number within the range of 0 to 0.6, g is a number within the range of 0 to 0.6, h is a number within the range of 0 to 0.9, i is a number within the range of 0 to 0.5, j is a number within the range of 0 to 0.05, and h+i is a number within the range of 0.4 to 0.9, f+g+h+i+i is 1.

Component (a₂₋₂) is an organopolysiloxane having at least two silicon atom bonded hydrogen atoms in one molecule, expressed by the average unit formula:

(R⁷₃SiO_{1/2})_{f}′(R⁷₂SiO_{2/2})_{g}′(R⁷SiO_{3/2})ₕ′(SiO_{4/2})ᵣ(R⁵O_{1/2})ⱼ′

In the formula, R⁷ and R⁵ are the same groups as described above.

In the formula, f′ is a number within the range of 0.01 to 0.3, g′ is a number within the range of 0.4 to 0.99, h′ is a number within the range of 0 to 0.2, i′ is a number within the range of 0 to 0.2, j′ is a number within the range of 0 to 0.1, and h′+i′ is a number within the range of 0 to 0.2, and f′+g′+h′+i′ is 1, preferably f′ is a number within the range of 0.02 to 0.20, g′ is a number within the range of 0.6 to 0.99, h′ is a number within the range of 0 to 0.1, i′ is a number within the range of 0 to 0.1, j′ is a number within the range of 0 to 0.05, and h′+i′ is a number within the range of 0 to 0.1, and f′+g′+h′+i′ is 1.

As described above, in component (a₂), the resinous organopolysiloxane having many branched siloxane units imparts hardness and mechanical strength to the cured product, and the obtained organopolysiloxane having many chained siloxane units imparts toughness to the cured product, and therefore, it is preferable to appropriately use component (a₂₋₁) and component (a₂₋₂) as component (a₂). Specifically, when the number of branched siloxane units in component (al) is small, it is preferable to mainly use component (a₂₋₁) as component (a₂), and when the number of chained siloxane units in component (a₁) is small, it is preferable to mainly use component (a₂₋₂). Component (a2) preferably has a mass ratio of component (a₂₋₁) to component (a₂₋₂) within the range of 50:50 to 100:0, or within the range of 60:40 to 100:0.

As component (a₂), the following organopolysiloxanes are exemplified. In the formula, Me and Ph represent a methyl group and a phenyl group, respectively.

Ph₂Si(OSiMe₂H)₂, i.e., Ph_{0.67}Me_{1.33}H_{0.67}SiO_{0.67}

HMe₂SiO(Me₂SiO)₂₀SiMe₂H, i.e., Me_{2.00}H_{0.09}SiO_{0.95}

HMe₂SiO(Me₂SiO)₅₅SiMe₂H, in other words, Me_{2.00}H_{0.04}SiO_{0.98}

PhSi(OSiMe₂H)₃, i.e., Ph_{0.25}Me_{1.50}H_{0.75}SiO_{0.75}

(HMe₂SiO_{1/2})_{0.6}(PhSiO3/2)_{0.4}, i.e., Ph_{0.40}Me_{1.20}H_{0.60}SiO_{0.90}

The amount of component (a₂) to be added is such that the molar ratio of silicon atom bonded hydrogen atoms in component (a₂) to the alkenyl groups in component (a₁) is in an amount of 0.2 to 0.7, preferably in an amount of 0.3 to 0.6. This is because the hardness and the mechanical strength of the obtained cured product are good when the amount of component (a₂) to be added is within the above ranges.

The organic peroxide used for radically reacting component (a₁) is not limited, and the organic peroxides exemplified by component (C) below can be used. In the radical reaction, component (a₁) is preferably a mixture of component (a₁₋₁) and component (a₁₋₂) in the mass ratio ranging from 10:90 to 90:10. Although the amount of the organic peroxide to be added is not limited, it is preferably within the range of 0.1 to 5 parts by mass, within the range of 0.2 to 3 parts by mass, or within the range of 0.2 to 1.5 parts by mass, based on 100 parts by mass of component (a₁).

The hydrosilylation reaction catalyst used for the hydrosilylation reaction of component (a₁) and component (a₂) is not limited, and a hydrosilylation reaction catalyst exemplified by component (C) below can be used. The amount of the hydrosilylation reaction catalyst to be added is preferably an amount in which platinum-based metal atoms in the hydrosilylation reaction catalyst are within the range of 0.01 to 500 ppm, within the range of 0.01 to 100 ppm, or within the range of 0.01 to 50 ppm in terms of mass units, with regard to the total amount of component (a₁) and component (a₂).

The above component (A₃) is obtained by condensing the following component (a₃) and the following component (a₄) with a condensation reaction catalyst.

Component (a₃) is a condensation reactive organopolysiloxane, expressed by the average unit formula:

(R⁸₃SiO_{1/2})ₚ(R⁸₂SiO_{2/2})_{q}(R⁸SiO_{3/2})ᵣ(SiO_{4/2})ₛ(R⁹O_{1/2})ₜ

In the formula, each R₈ is independently an alkyl group having 1 to 20 carbon atoms, a halogen-substituted alkyl group having 1 to 20 carbon atoms, an alkenyl group having 2 to 20 carbon atoms, an aryl group having 6 to 20 carbon atoms, a halogen-substituted aryl group having 6 to 20 carbon atoms, or an aralkyl group having 7 to 20 carbon atoms, and the same groups as described above are exemplified. Furthermore, in the formula, R⁹ is a hydrogen atom, an alkyl group having 1 to 6 carbon atoms, or an acyl group having 2 to 5 carbon atoms, and an alkoxy group such as a methoxy group or an ethoxy group and an acyloxy group are exemplified. Component (a₃) has at least one silicon-bonded hydroxyl group, silicon-bonded alkoxy group, or silicon-bonded alkoxy group in one molecule. In addition, it is preferable that in one molecule, at least two R⁸ is an alkenyl group, and 10 mol % or more, or 20 mol % or more of the total R⁸ is a phenyl group.

In the formula, p is a number within the range of 0 to 0.7, q is a number within the range of 0 to 0.7, r is a number within the range of 0 to 0.9, s is a number within the range of 0 to 0.7, t is a number within the range of 0.01 to 0.10, and r+s is a number within the range of 0.3 to 0.9, p+q+r+s is 1, and preferably p is a number within the range of 0 to 0.6, q is a number within the range of 0 to 0.6, r is a number within the range of 0 to 0.9, s is a number within the range of 0 to 0.5, t is a number within the range of 0.01 to 0.05, and r+s is a number within the range of 0.4 to 0.9. This is because, when p, q, and r+s are each a number within the above range, a hot-melt silicone having flexibility at 25° C. but non-fluidity, low surface tack, and sufficiently low melt viscosity at high temperature is obtained.

Component (a4) is a condensation reactive organopolysiloxane, expressed by the average unit formula:

(R⁸₃SiO_{1/2})ₚ′(R⁸₂SiO_{2/2})′(R⁸SiO_{3/2})ᵣ′(SiO_{4/2})ₛ′(R⁹O_{1/2})ₜ′

In the formula, R⁸ and R⁹ are the same groups as described above. Component (a₄) has at least one silicon-bonded hydroxyl group, silicon-bonded alkoxy group, or silicon-bonded acyloxy group in one molecule. In the formula, p′ is a number within the range of 0.01 to 0.3, q′ is a number within the range of 0.4 to 0.99, r′ is a number within the range of 0 to 0.2, s′ is a number within the range of 0 to 0.2, t′ is a number within the range of 0 to 0.1, and r′+s′ is a number within the range of 0 to 0.2, p′+q′+r′+s′ is 1, and preferably p′ is a number within the range of 0.02 to 0.20, q′ is a number within the range of 0.6 to 0.99, r′ is a number within the range of 0 to 0.1, s′ is a number within the range of 0 to 0.1, t′ is a number within the range of 0 to 0.05, and r′+s′ is a number within the range of 0 to 0.1. This is because, when p′, q′, r′, and s′ are each a number within the above range, a hot-melt silicone having flexibility at 25° C. but non-fluidity, low surface tack, and sufficiently low melt viscosity at high temperature is obtained.

The condensation reaction catalyst for condensation reaction of component (a₃) and component (a₄) is not limited, and examples thereof include organic tin compounds such as dibutyltin dilaurate, dibutyltin diacetate, tin octenate, dibutyltin dioctate, and tin laurate; organic titanium compounds such as tetrabutyl titanate, tetrapropyl titanate, and dibutoxy bis(ethyl acetoacetate); acidic compounds such as hydrochloric acid, sulfuric acid, and dodecylbenzene sulfonic acid; alkaline compounds such as ammonia and sodium hydroxide; and amine-based compounds such as 1,8-diazabicyclo[5.4.0]undecene (DBU), 1,4-diazabicyclo[2.2.2]octane (DABCO), and preferably an organic tin compound, and an organic titanium compound.

Component (A₃) is a block copolymer composed of a resinous organosiloxane block and a chained organosiloxane block. Such component (A₃) is preferably comprised of 40 to 90 mol % of disiloxy units of the formula [R¹₂SiO_{2/2}], 10 to 60 mol % of trisiloxy units of the formula [R¹SiO_{3/2}], and preferably contains 0.5 to 35 mol % of silanol groups [≡SiOH]. Here, each R¹ is independently an alkyl group having 1 to 20 carbon atoms, a halogen-substituted alkyl group having 1 to 20 carbon atoms, an alkenyl group having 2 to 20 carbon atoms, an aryl group having 6 to 20 carbon atoms, a halogen-substituted aryl group having 6 to 20 carbon atoms, or an aralkyl group having 7 to 20 carbon atoms, and the same groups as described above are exemplified. At least two R¹ in one molecule is an alkenyl group. Further, component (A₃) is a resinous organosiloxane block copolymer in which the disiloxy unit [R¹₂SiO_{2/2}] forms a linear block having on average 100 to 300 disiloxy units per one linear block; the trisiloxy unit [R¹SiO_{3/2}] forms a non-linear block having a molecular weight of at least 500 g/mol; at least 30% of the non-linear blocks are bonded to each other; each linear block is bonded to at least one non-linear block via a —Si—O—Si— linkage; the resinous organosiloxane block copolymer having a mass-average molecular weight of at least 20000 g/mol, and containing at least one alkenyl group of 0.5 to 4.5 mol %.

Component (A₃) is prepared by condensation reaction of (a₅) a resinous organosiloxane or a resinous organosiloxane block copolymer with (a₆) a chained organosiloxane, and optionally (a₇) a siloxane compound.

Component (a₅) is a resinous organopolysiloxane, expressed by the average unit formula:

[R¹₂R²SiO_{1/2}]ᵢ[R¹R²SiO_{2/2}]ᵢᵢ[R¹SiO_{3/2}]ᵢᵢi[R²SiO_{3/2}]ᵢᵥ[SiO_{4/2}]ᵥ

In the formula, each R¹ is independently an alkyl group having 1 to 20 carbon atoms, a halogen-substituted alkyl group having 1 to 20 carbon atoms, an alkenyl group having 2 to 20 carbon atoms, an aryl group having 6 to 20 carbon atoms, a halogen-substituted aryl group having 6 to 20 carbon atoms, or an aralkyl group having 7 to 20 carbon atoms, and the same groups as described above are exemplified. In addition, in the formula, each R² is independently an alkyl group having 1 to 20 carbon atoms, a halogen-substituted alkyl group having 1 to 20 carbon atoms, an aryl group having 6 to 20 carbon atoms, a halogen-substituted aryl group having 6 to 20 carbon atoms, or an aralkyl group having 7 to 20 carbon atoms, and the same groups as the R¹ are exemplified.

Also, in the formula, i, ii, iii, iv, and v represent the mole fraction of each siloxy unit, i is a number from 0 to 0.6, ii is a number from 0 to 0.6, iii is a number from 0 to 1, iv is a number from 0 to 1, and v is a number from 0 to 0.6, with the proviso that (ii+iii+iv+v) >0 and (i+ii+iii+iv+v) ≤1. In addition, component (a₅) preferably contains 0 to 35 mol % of a silanol group [≡SiOH] in one molecule.

Component (a₆) is a straight-chain organosiloxane expressed by general formula:

R¹₃₋ₐ(X)ₐSiO(R¹₂SiO)_{β}Si(X)_{α}R¹_{3-α}

In the formula, R¹ is the same as described above, and the same groups as described above are exemplified. In addition, in the formula, X is a hydrolyzable group selected from —OR⁵, F, Cl, Br, I, —OC(O)R⁵, —N(R⁵)₂, or —ON═CR⁵₂, (wherein R⁵ is a hydrogen atom or an alkyl group having 1 to 6 carbon atoms) . Furthermore, in the formula, α is independently 1, 2, or 3, and 13 is an integer of 50 to 300.

Component (a₇) is a siloxane compound expressed by general formula:

R¹R²₂SiX

In the formula, R¹, R², and X are the same groups as described above.

The condensation reaction catalyst for condensation reaction of component (a₅) and component (a₆) and/or component (a₇) is not limited, and examples thereof include organic tin compounds such as dibutyltin dilaurate, dibutyltin diacetate, tin octenate, dibutyltin dioctate, and tin laurate; organic titanium compounds such as tetrabutyl titanate, tetrapropyl titanate, and dibutoxy bis(ethyl acetoacetate); acidic compounds such as hydrochloric acid, sulfuric acid, and dodecylbenzene sulfonic acid; alkaline compounds such as ammonia and sodium hydroxide; amine-based compounds such as 1,8-diazabicyclo[5.4.0]undecene (DBU), 1,4-diazabicyclo[2.2.2]octane (DABCO).

With the present invention, a particularly suitable component (A1) is a block copolymer made up of (A₃) resinous organosiloxane block and a chain organosiloxane block, where siloxane units selected from siloxane units represented by RSiO_{3/2} (in the formula, R is a monovalent organic group) and siloxane units represented by SiO_{4/2} are in the range of 25 to 75 mol % of the total siloxane units, and having siloxane units represented by R^{A}SiO_{3/2} (in the formula, R^{A} is an aryl group with 6 to 20 carbon atoms) in the molecule.

In particular, component (A1) is suitably in the form of organopolysiloxane microparticles having hot-melt properties, where 10 mol % or more, and suitably 15 to 50 mol %, of all organic groups in the molecule are aryl groups, in particular, phenyl groups. On the other hand, in the present invention, as long as component (A1) satisfies the structure described above, it may be used without restriction, but since the structure of component (A1) greatly affects the curing behavior of the entire composition, the melting point of the entire (A1) component is preferably 200° C. or lower. On the other hand, the so-called MQ resin, which consists of a siloxane unit represented by R′₃SiO_{1/2} (M unit, where R′ is an organic group other than an aryl group) and a siloxane unit represented by SiO_{4/2} (Q unit), generally has a melting point of greater than 200° C. Therefore, designing for a melting point of component (A1), that is a mixture, of 200° C. or less, suitably in the range of 25° C. to 200° C., by setting the content of aryl groups, in particular phenyl groups, of the organic groups in the molecule, high and mixing an appropriate ratio of other components (A1) with a melting point of less than 200° C. is preferable. If the number of MQ resin components with a high melting point increases, the loss tangent (tanδ) thereof tends to increase when the curing behavior of the composition of the present invention is measured by MDR, and may become inappropriate as a means of solving the problem of the present invention.

If there is intent to impart hot-melt properties to the composition of the present invention, component (A1) is preferably an organopolysiloxane resin in the form of microparticles, suitably spherical organopolysiloxane resin microparticles having an average primary particle diameter of 1 to 20 μm as measured using a laser diffraction/scattering method or the like. By using such a particulate component, the composition can be prepared or produced as a hot-melt curable composition having superior handling workability and hot-melt properties. The manufacturing method is either that component (A) is simply atomized or is a process where at least two kinds of organopolysiloxanes are crosslinked and a process where the reactants are atomized are performed simultaneously or separately.

The method of producing the microparticles (A1) component includes, for example, a method of pulverizing the organopolysiloxane resin described above using a pulverizer, or a method of direct micronization in the presence of a solvent. The pulverizer may be, for example, but not limited to, a roll mill, a ball mill, a jet mill, a turbo mill, or a planetary mill. Examples of a method of directly atomizing the organopolysiloxane in the presence of a solvent, for example, spraying by a spray dryer, or atomization by a biaxial kneader or a belt dryer. When obtaining the particulate polyorganosiloxane, component (A1) with a different structure, other organopolysiloxane components, and the curing catalyst described below, such as a hydrosilylation reaction catalyst, may be particulated together, but from the viewpoint of storage stability of the resulting composition, it is recommended that the mixture can be cured by heat. However, from the viewpoint of the storage stability of the resulting composition, it is advisable to avoid micronization of the heat-curable mixture. Specifically, it is preferable to particulate component (A1), other (A) components, and a portion of component (C), and add the remaining components by the method described below to obtain the composition. In the present invention, the use of spherical hot-melt silicone microparticles obtained by spraying with a spray dryer is particularly preferable from the viewpoints of the melting characteristics of the granular compound, the flexibility of the cured product, the compounded amount of component (B), efficiency during manufacture, and workability of the composition.

By using a spray dryer or the like, component (A) or component (A1) having a true spherical shape and an average primary particle diameter of 1 to 500 μm can be produced. The heating and drying temperature of the spray dryer needs to be appropriately set based on the heat resistance of the silicone fine particles and the like. In order to prevent secondary aggregation of the silicone fine particles, it is preferable to control the temperature of the silicone fine particles to be equal to or lower than the glass transition temperature thereof. The silicone fine particles thus obtained can be recovered by a cyclone, a bag filter, or the like.

In order to obtain a uniform component (A) or component (A1), a solvent may be used in the above-mentioned step within a range that does not inhibit the curing reaction. Examples of the solvents include, but are not limited to, aliphatic hydrocarbons such as n-hexane, cyclohexane, and n-heptane; aromatic hydrocarbons such as toluene, xylene, and mesitylene; ethers such as tetrahydrofuran and dipropyl ether; silicones such as hexamethyldisiloxane, octamethyltrisiloxane, and decamethyltetrasiloxane; esters such as ethyl acetate, butyl acetate, and propylene glycol monomethyl ether; and ketones such as acetone, methyl ethyl ketone, and methyl isobutyl ketone.

Component (A) may include a curable reactive organopolysiloxane other than component (A1) described above. For example, straight or branched-chain organopolysiloxanes where the content of siloxane units represented by RSiO_{3/2} (in which R is a monovalent organic group) and siloxane units represented by SiO_{4/2} is less than 20 mol %, and having a curing-reactive functional group containing at least one, suitably two or more carbon-carbon double bonds in the molecule. The groups above are examples of curing reactive functional groups, but it is preferable to have a hydrosilylation reactive or organic peroxide curing functional group, especially a vinyl group or a hexenyl group. The binding site of the curing-reactive functional group may be at the end of the molecular chain or at a side chain (pendant site) of the siloxane molecular chain. The functional group other than the curing-reactive functional group containing a carbon-carbon double bond is not particularly limited, but may be an alkyl group, an aryl group, a hydroxyl group or an alkoxy group which may be substituted with a halogen atom.

[Component (B)]

The functional filler, which is component (B) of the present invention, is a component that imparts mechanical and other properties to the cured product, and when cured under high temperature after heating and melting (hot melt), the cured product has the desired functions, and depending on the selection and compounded amount of component (B), a cured product having superior hardness and toughness at room temperature to high temperature can be provided. Inorganic fillers, organic fillers, and mixtures thereof are examples of component (B). Examples of the inorganic fillers include a reinforcing filler, a white pigment, a thermally conductive filler, an electrically conductive filler, a phosphor, and mixtures of at least two of these, and examples of organic fillers include a silicone resin filler, a fluorine resin filler, and a polybutadiene resin filler. The shape of these fillers is not particularly limited, and may be spherical, spindle-shaped, flat, needle-shaped, amorphous, or the like.

When the composition is used in applications such as an encapsulant, a protective agent, an adhesive, a light reflective material, and the like, a reinforcing filler is preferably included in at least a part of component (B) from the viewpoint of improving the mechanical strength, protectiveness, and adhesiveness of the cured product.

Reinforcing fillers may be added to improve the mechanical strength of the cured product, to improve protection and adhesion, and to maintain a solid particle shape as a binder filler in the curable granular silicone composition before curing. Examples of this type of reinforcing filler include fumed silica, precipitated silica, fused silica, calcined silica, fumed titanium dioxide, quartz, calcium carbonate, diatomaceous earth, aluminum oxide, aluminum hydroxide, zinc oxide, and zinc carbonate. These reinforcing fillers may also be surface treated with organoalkoxysilanes such as methyltrimethoxysilane;

organohalosilanes such as trimethylchlorosilane; organosilazanes such as hexamethyldisilazane; siloxane oligomers such as α,ω-silanol group-blocked dimethylsiloxane oligomers, α,ω-silanol group-blocked methylphenylsiloxane oligomers, α,ω-silanol group-blocked methylvinylsiloxane oligomers, and the like. The particle size of the reinforcing filler is not restricted, but the median diameter measured by a laser diffraction scattering type particle size distribution measurement is preferably within a range of 1 nm to 500 μm. Further, as the reinforcing filler, a fibrous filler such as calcium metasilicate, potassium titanate, magnesium sulfate, sepiolite, zonolite, aluminum borate, rock wool, glass fiber, or the like may be used.

Here, component (B) is preferably an inorganic filler substantially free of coarse particles having an average particle diameter of 10.0 μm or more, and in particular when the curable silicone composition for transfer molding of the present invention is hot-melt, a curable silicone composition having excellent gap-filling properties when melted and cures to give a flexible cured product at room to high temperatures can be provided. The term “substantially free of coarse particles having an average particle diameter of 10.0 μm or more or 5.0 μm or more” means that no coarse particles having an average particle diameter of the long diameter of the particle being 10.0 μm or more or 5.0 μm or more are observed when component (B) is observed using an electron microscope or the like, or that the volume ratio of coarse particles having an average particle diameter of 10.0 μm or more or 5.0 μm or more is less than 1% when the particle diameter distribution of component (B) is measured using a measurement using a laser diffraction/scattering type particle size distribution or the like.

In addition, when the cured silicone composition for transfer molding of the present invention has hot-melt properties, from the viewpoint of providing favorable gap-filling properties during melting and flexibility of the cured product at room temperature to high temperature, components (B) include (b1) an inorganic filler with an average particle diameter of 0.1 μm or less, suitably a reinforcing filler and (b2) an inorganic filler having an average particle diameter of 0.1 to 5.0 μm, suitably a mixture of reinforcing fillers. The ratio of the two is arbitrary, but may be a mass ratio of 1/99 to 20/80, 1/99 to 50/50, or 5/95 to 40/60. In particular, containing (b1-1) fumed silica having an average particle diameter of 0.1 μm or less, suitably 0.05 μm or less, and (b2-1) fused silica having an average particle diameter of 0.1 to 5.0 μm, suitably 0.15 to 4.0 μm, in a mass ratio of 1/99 to 20/80 suitably 1/99 to 50/50, and more suitably a mass ratio of 5/95 to 40/60 is preferable. In particular, when the particles of such a mixture of inorganic fillers are the same or smaller in size than the particle size of the hot-melt organopolysiloxane microparticles, which are the component (A), a favorable silicon-filler matrix can be formed upon melting. This improves the flexibility and mechanical strength of the cured product. Favorable gap-filling properties can also be achieved because the material is substantially free of coarse particles.

Further, a white pigment, a thermally conductive filler, an electrically conductive filler, or a phosphor may be blended for the purpose of imparting other functions to the cured product obtained using the composition. Organic fillers such as silicone elastomer particles may also be blended for the purpose of improving the stress relaxation properties of the cured product.

The white pigment is a component that imparts whiteness to the cured product and improves light reflectivity, and the cured product resulting from curing the composition by blending the component can be used as a light reflective material for light emitting/optical devices. Examples of the white pigment include metal oxides such as titanium oxide, aluminum oxide, zinc oxide, zirconium oxide, magnesium oxide, and the like; hollow fillers such as glass balloons, glass beads, and the like; and other barium sulfate, zinc sulfate, barium titanate, aluminum nitride, boron nitride, and antimony oxide. Titanium oxide has high optical reflectivity and concealing properties, and is therefore preferable. Furthermore, aluminum oxide, zinc oxide, and barium titanate have high optical reflectivity of a UV region, and are therefore preferable. The average particle size or shape of the white pigment is not restricted, but the average particle diameter is within a range of 0.05 to 10.0 μm and preferably within a range of 0.1 to 5.0 82 m. Furthermore, a surface of the white pigment can be treated by a silane coupling agent, silica, aluminum oxide, and the like.

A thermally conductive filler or an electrically conductive filler is added to the cured product for the purpose of imparting thermal conductivity/electrical conductivity thereto, and specific examples include a metallic fine powder such as gold, silver, nickel, copper or aluminum; a fine powder such as ceramic, glass, quartz or organic resin, the surface thereof on which a metal such as gold, silver, nickel, or copper is deposited or plated; a metallic compound such as aluminum oxide, magnesium oxide, aluminum nitride, boron nitride or zinc oxide or the like; and graphite, and mixtures of two or more of these. When electrical insulation is required for the present composition, a metal oxide-based powder or a metal nitride-based powder is preferable, and in particular, an aluminum oxide powder, a zinc oxide powder, or an aluminum nitride powder is preferable and combinations of type, particle diameter, and particle shape and the like can be used according to these thermal conductivity/electrical conductivity requirements.

Phosphor is a component that is blended to convert the emission wavelength from a light source (optical semiconductor device) when the cured product is used as a wavelength conversion material. There is no particular limitation on this phosphor, and examples of the phosphor include yellow, red, green, and blue light phosphors, which include oxide phosphors, oxynitride phosphors, nitride phosphors, sulfide phosphors, oxysulfide phosphors, and the like, which are widely used in light emitting diodes (LED).

Silicone microparticles include non-reactive silicone resin microparticles and silicone elastomer microparticles, but silicone elastomer microparticles are suitably exemplified from the viewpoint of improving cured product flexibility or stress relaxation properties.

The silicone elastomer fine particles are a crosslinked product of linear diorganopolysiloxane comprised of primarily of diorganosiloxy units (D-units). The silicone elastomer fine particles can be prepared by a crosslinking reaction of diorganopolysiloxane by a hydrosilylation reaction, a condensation reaction of a silanol group, or the like, and in particular, the silicone elastomer fine particles can be suitably obtained by a crosslinking reaction of organohydrogenpolysiloxane having a silicon bonded hydrogen atom at a side chain or a terminal with diorganopolysiloxane having an unsaturated hydrocarbon group such as an alkenyl group at a side chain or a terminal under a hydrosilylation reaction catalyst. The silicone elastomer fine particles may have various shapes such as spherical, flat, and irregular shapes, but are preferably spherical in terms of dispersibility, and among these, true spherical is more preferable. Commercial products of such silicone elastomer fine particles include, for example, “Torefil-E series” and “EP Powder series” manufactured by Dow Corning Toray Company, Ltd., and “KMP series” manufactured by Shin-Etsu Chemical Co., Ltd.

For the purpose of stably blending the functional filler above in the present composition or the like, the filler surface may be treated using a specific surface treatment agent in the range of 0.1 to 2.0 mass %, 0.1 to 1.0 mass %, or 0.2 to 0.8 mass % of the total mass of component (B). Examples of these surface treatment agents include, methylhydrogen polysiloxane, silicone resins, metal soaps, silane coupling agents, perfluoroalkyl silanes, as well as fluorine compounds such as perfluoroalkyl phosphate ester salts.

Although the content of component (B) is not limited, in the composition of the present invention, the content of component (B) is preferably in the range of 10 to 40 volume % of the entire composition, and more suitably in the range of 10 to 30 volume %, to achieve superior hardness and mechanical strength of the cured product. If the content of component (B) exceeds the upper limit, the cured product obtained tends to become hard, and the maximum torque value obtained by measuring the MDR of the composition tends to be high, which may be unsuitable for solving the problem of the present invention.

[Component (C)]
Component (C) is a curing agent for curing component (A), and is not limited to those capable of curing component (A), but is preferably one or more of the following curing agents selected from (c1) or (c2). Two or more of these curing agents may be used in combination, for example, the cure system may include both a (c1) component and a (c2) component.
(c1) An organic peroxide
(c2) An organohydrogenpolysiloxane having at least two silicon-bonded hydrogen atoms in the molecule and a hydrosilylation reaction catalyst

(c1) Organic peroxide is a component that cures component (A) described above by heating, and examples include alkyl peroxides, diacyl peroxides, ester peroxides, and carbonate peroxides.

Examples of alkyl peroxides include dicumyl peroxide, di-tert-butyl peroxide, di-tert-butylcumyl peroxide, 2,5-dimethyl-2,5-di(tert-butylperoxy)hexane, 2,5-dimethyl-2,5-di(tert-butylperoxy)hexyne-3, tert-butylcumyl, 1,3-bis(tert-butylperoxyisopropyl)benzene, and 3,6,9-triethyl-3,6,9-trimethyl-1,4,7-triperoxonan.

Examples of diacyl peroxides include benzoyl peroxide, lauroyl peroxide, and decanoyl peroxide.

Examples of ester peroxides include 1,1,3,3-tetramethylbutylperoxyneodecanoate, α-cumylperoxyneodecanoate, tert-butylperoxyneodecanoate, tert-butylperoxyneoheptanoate, tert-butylperoxypivalate, tert-hexylperoxypivalate, 1,1,3,3-tetramethylbutylperoxy-2-ethylhexanoate, tert-amylperoxyl-2-ethylhexanoate, tert-butylperoxy-2-ethylhexanoate, tert-butylperoxyisobutyrate, di-tert-butylperoxyhexahydroterephthalate, tert-amylperoxy-3,5,5-trimethylhexanoate, tert-butylperoxy-3,5,5-trimethylhexanoate, tert-butylperoxyacetate, tert-butylperoxybenzoate, and di-butylperoxytrimethyladipate.

Examples of carbonate peroxides include di-3-methoxybutyl peroxydicarbonate, di(2-ethylhexyl)peroxydicarbonate, diisopropyl peroxycarbonate, tert-butyl peroxyisopropylcarbonate, di(4-tert-butylcyclohexyl)peroxydicarbonate, dicetyl peroxydicarbonate, and dimyristyl peroxydicarbonate.

This organic peroxide preferably has a 10-hour half-life temperature of not lower than 90° C. or not lower than 95° C. Examples of such organic peroxide include dicumyl peroxide, di-tert-butyl peroxide, di-tert-hexyl peroxide, tert-butylcumyl peroxide, 2,5-dimethyl-2,5-di(tert-butylperoxy)hexane, 1,3-bis(tert-butylperoxyisopropyl)benzene, di-(2-tert-butylperoxyisopropyl)benzene, and 3,6,9-triethyl-3,6,9-trimethyl-1,4,7-triperoxonan.

While not limited thereto, the content of the (c1) organic peroxide is preferably within the range of 0.05 to 10 parts by mass, or within the range of 0.10 to 5.0 parts by mass, with regard to 100 parts by mass of (A).

The organohydrogenpolysiloxane having at least two silicon-bonded hydrogen atoms in the (c2) molecule and the hydrosilylation reaction catalyst are components that cure the composition by an addition reaction (hydrosilylation reaction) of the organohydrogenpolysiloxane, a crosslinking agent, with the carbon-carbon double bond in component (A) in the presence of the hydrosilylation reaction catalyst.

Organohydrogenpolysiloxane, which is a part of this type of component (c2), is not limited regarding obtaining the molecular structure thereof, and may be one or more types selected from the components (a2), in particular the chain-like organohydrogenpolysiloxane exemplified as component (a2-1), and the organohydrogenpolysiloxane resin exemplified as component (a2-2), or one or more types selected from a mixture thereof. Particularly, straight-chain organohydrogenpolysiloxanes having silicon-bonded hydrogen atoms at least at both terminals of the molecular chain and having a siloxane polymerization degree of 2 to 200, suitably 3 to 100, are preferred, suitable examples of which are as follows In the formula, Me and Ph represent a methyl group and a phenyl group, respectively.

Ph₂Si(OSiMe₂H)₂, i.e., Ph_{0.67}Me_{1.33}H_{0.67}SiO_{0.67}

HMe₂SiO(Me₂SiO)₂₀SiMe₂H, i.e., Me_{2.00}H_{0.09}SiO_{0.95}

HMe₂SiO(Me₂SiO)₅₅SiMe₂H, in other words, Me_{2.00}H_{0.04}SiO_{0.98}

PhSi(OSiMe₂H)₃, i.e., Ph_{0.25}Me_{1.50}H_{0.75}SiO_{0.75}

(HMe₂SiO_{1/2})_{0.6}(PhSiO_{3/2})_{0.4}, i.e., Ph_{0.40}Me_{1.20}H_{0.60}SiO_{0.90}

The amount of the organohydrogenpolysiloxane, which is a part of component (c2), is an amount sufficient to cure the curable granular silicone composition of the present invention and relative to the curable reactive functional group (for example, an alkenyl group such as a vinyl group) containing a carbon-carbon double bond in component (A), the molar ratio of the silicon-bonded hydrogen atom in the organohydrogenpolysiloxane is 0.5 or more and preferably in the range of 0.5 to 20. In particular, when component (c2) includes the organohydrogenpolysiloxane resin described above, the amount thereof is set so that, relative to the curable reactive functional group containing a carbon-carbon double bond in component (A), the molar ratio of the silicon-bonded hydrogen atom in the organohydrogenpolysiloxane resin is in the range of 0.5 to 20 and preferably in the range of 1.0 to 10.

Examples of the hydrosilylation reaction catalyst that is a part of component (c2) include platinum-based catalysts, rhodium-based catalysts, and palladium-based catalysts. Platinum-based catalysts are preferred due to the ability to remarkably promote curing of the present composition. Exemplary platinum-based catalysts include platinum fine powder, chloroplatinic acid, an alcohol solution of chloroplatinic acid, a platinum-alkenyl siloxane complex, a platinum-olefin complex, a platinum-carbonyl complex, and a catalyst in which these platinum-based catalysts are dispersed or encapsulated with a thermoplastic resin such as silicone resin, polycarbonate resin, acrylic resin or the like, with a platinum-alkenyl siloxane complex particularly preferable. Exemplary alkenylsiloxanes include: 1,3-divinyl-1,1,3,3-tetramethyldisiloxane; 1,3,5,7-tetramethyl-1,3,5,7-tetravinylcyclotetrasiloxane; alkenyl siloxanes obtained by substituting a portion of methyl groups of the alkenylsiloxanes with an ethyl group, a phenyl group, or the like; and alkenylsiloxanes obtained by substituting a portion of vinyl groups of these alkenylsiloxanes with an allyl group, a hexenyl group, or the like. In particular, 1,3-divinyl-1,1,3,3-tetramethyldisiloxane is preferably used because of the favorable stability of this platinum-alkenylsiloxane complex, and is preferably added in the form of a complex alkenylsiloxane solution. In addition, in terms of improving the handleability as well as the pot life of the composition, a platinum containing hydrosilylation reaction catalyst in fine particles dispersed and encapsulated with thermoplastic resin may be used. As the catalyst for promoting the hydrosilylation reaction, a non-platinum based metal catalyst such as iron, ruthenium, iron/cobalt, or the like may be used.

The amount of the hydrosilylation reaction catalyst, which is a part of component (c2), should be an amount in which a metal atom is in the range of 0.01 to 500 ppm, 0.01 to 100 ppm, or preferably 0.01 to 50 ppm by mass relative to the entire composition.

A particularly suitable (c2) component is a component (c2-1) containing at least dimethylorganopolysiloxane having silicon-bonded hydrogen atoms at both terminals of the molecular chain and a hydrosilylation reaction catalyst.

The curable granular silicone composition of the present invention comprises the components (A) to (C) described above, and from the viewpoint of further improving the melting characteristics thereof, (D) hot-melt particles with a drip point of 50° C. or higher and a melt viscosity measured by a rotational viscometer at 150° C. of less than 10 Pa·s may be added and is preferable.

The type of component (D) is not particularly limited, and one or more types selected from various hot-melt synthetic resins, waxes, fatty acid metal salts, and the like can be used, as long as the conditions of the drip point described above and kinematic viscosity at 150° C. during melting are satisfied. The component (D) exhibits low kinematic viscosity at high temperatures (150° C.) and forms a melt with excellent flowability. Furthermore, by combining the components (A) to (C) described above, component (D) in the melt that makes up the present composition spreads quickly throughout the composition at high temperature, thereby lowering the viscosity of the substrate surface to which the molten composition is applied and of the composition as a whole, rapidly lowering the surface friction of the substrate and the molten composition, and significantly increasing the fluidity of the composition as a whole. Therefore, the viscosity and flowability of the molten composition can be greatly improved by adding only a very small amount to the total amount of other components.

The component (D) may be a petroleum wax such as paraffin as long as it satisfies the conditions of drip point and kinematic viscosity at the time of melting described above, but from the viewpoint of the technical effect of the present invention, a hot melt component that makes up a fatty acid metal salt is preferable, and a metal salt of a higher fatty acid such as stearic acid, palmitic acid, oleic acid and isononanoic acid is particularly preferable. Here, the types of the fatty acid metal salts described above are also not particularly limited, and suitable examples include alkali metal salts such as lithium, sodium, potassium, and the like; alkaline earth metal salts such as magnesium, calcium, barium, and the like; or zinc salts.

Particularly suitable as component (D) are fatty acid metal salts having a (D0) free fatty acid content of 5.0% or less, 4.0% or less, and more preferably fatty acid metal salts with 0.05 to 3.5% of free fatty acid content. Examples of such a component (D0) include at least one or more stearic acid metal salts. From the viewpoint of the technical effect of the present invention, component (D0) preferably consists substantially only of one or more stearic acid metal salts, a hot-melt component with a melting point of 150° C. or less selected from calcium stearate (melting point 150° C.), zinc stearate (melting point 120° C.), and magnesium stearate (melting point 130° C.).

Regarding the amount of component (D) used, with the entire composition taken as 100 mass parts, the content of component (D0) is in the range of 0.01 to 5.0 parts by mass, and may be 0.01 to 3.5 parts by mass, or 0.01 to 3.0 parts by mass. If the amount of component (D) used exceeds the upper limit, the adhesiveness and mechanical strength of the cured product obtained from the cured silicone composition for transfer molding of the present invention may be insufficient. If the amount of component (D) used is less than the lower limit, sufficient fluidity while heating and melting may not be achieved.

The present composition may contain a curing retardant or an adhesion imparting agent as other optional components as long as the object of the present invention is not impaired.

Examples of the curing retardant include: alkyne alcohols such as 2-methyl-3-butyne-2-ol, 3,5-dimethyl-1-hexyne-3-ol, 2-phenyl-3-butyne-2-ol, and 1-ethynyl-1-cychlohexanol; enyne compounds such as 3-methyl-3-pentene-1-yne, and 3,5-dimethyl-3-hexene-1-yne; alkenyl group-containing low molecular weight siloxanes such as tetramethyltetravinylcyclotetrasiloxane and tetramethyltetrahexenylcyclotetrasiloxane; and alkynyloxysilanes such as methyl tris(1,1-dimethyl propynyloxy)silane and vinyl tris(1,1-dimethyl propynyloxy)silane. The content of the curing retardant is not limited, but is preferably within the range of 10 to 10000 ppm in terms of mass units, with regard to the composition.

As the adhesion imparting agent, an organosilicon compound having at least one alkoxy group bonded to a silicon atom in one molecule is preferable. Examples of this alkoxy group include a methoxy group, an ethoxy group, a propoxy group, a butoxy group, and a methoxyethoxy group, with a methoxy group particularly preferable. Moreover, examples of groups other than alkoxy group, bonded to the silicon atom of the organosilicon compound include: halogen substituted or unsubstituted monovalent hydrocarbon groups such as an alkyl group, an alkenyl group, an aryl group, an aralkyl group, and a halogenated alkyl group; glycidoxyalkyl groups such as a 3-glycidoxypropyl group and a 4-glycidoxybutyl group; epoxycyclohexylalkyl groups such as a 2-(3,4-epoxycyclohexyl)ethyl group and a 3-(3,4-epoxycyclohexyl)propyl group; epoxyalkyl groups such as a 3,4-epoxybutyl group and a 7,8-epoxyoctyl group; acryl group-containing monovalent organic groups such as a 3-methacryloxypropyl group; and hydrogen atoms. This organosilicon compound preferably has a group that may react with an alkenyl group or a silicon atom-bonded hydrogen atom in this composition, and specifically, preferably has a silicon atom-bonded hydrogen atom or an alkenyl group. Moreover, because favorable adhesion can be imparted to various substrates, this organosilicon compound preferably has at least one epoxy group-containing monovalent organic group per one molecule. Examples of such an organosilicon compound include an organosilane compound, an organosiloxane oligomer, and an alkyl silicate. Exemplary molecular structures of this organosiloxane oligomer or alkyl silicate include a linear structure, a partially branched linear structure, a branched structure, a cyclic structure, and a network structure, among which a linear structure, a branched structure, and a network structure are particularly preferable. Examples of the organic silicon compound include silane compounds such as 3-glycidoxypropyltrimethoxysilane, 2-(3,4-epoxycyclohexyl) ethyltrimethoxysilane, and 3-methacryloxypropyltrimethoxysilane; siloxane compounds with at least one of each of a silicon-bonded alkenyl group or a silicon-bonded hydrogen atom and a silicon-bonded alkoxy group in one molecule; a silane compound or siloxane compound having at least one silicon-bonded alkoxy group; a mixture of siloxane compounds having at least one each of silicon-bonded alkenyl group and silicon-bonded alkenyl group in one molecule, a reaction mixture of an amino group-containing organoalkoxysilane and an epoxy group-containing organoalkoxysilane, and an organic compound having at least two alkoxysilyl groups containing bonds other than silicon-oxygen bonds between their silyl groups in one molecule; general formula: R^{a}ₙSi(OR^{b})₄₋ₙ (wherein, R^{a} represents an organic group containing a monovalent epoxy group, R^{b} represents an alkyl group having a carbon number of 1 to 6, or a hydrogen atom. n represents a number within a range of 1 to 3), representing epoxy group-containing silane or a partially hydrolyzed condensate, reaction mixture of vinyl group-containing siloxane oligomer (including chain or ring shaped structure) and epoxy group-containing trialkoxysilane, methyl polysilicate, ethyl polysilicate, and epoxy group-containing ethyl polysilicate. The adhesion imparting agent is preferably in the form of a low viscosity liquid, and the viscosity thereof is not limited, but is preferably within the range of 1 to 500 mPa·s at 25° C. In addition, while not limited thereto, the content of this adhesion imparting agent is preferably within the range of 0.01 to 10 parts by mass with regard to 100 parts by mass of the total of the present composition.

Furthermore, the composition may contain, as other optional components, heat resistance agents such as iron oxide (red iron oxide), cerium oxide, cerium dimethyl silanolate, fatty acid cerium salt, cerium hydroxide, zirconium compound, and the like; and dyes, pigments other than white, flame retardant agents, and the like may be contained as long as the purpose of the present invention is not impaired.

[Form of Composition]

The curable silicone composition for transfer molding of the present invention may be a non-flowing solid or a paste or semi-solid at 25° C. Since the curable silicone composition is used for transfer molding applications, the curable silicone composition is in particular preferably a solid having a softening point below 100° C. and having heat-melting properties. On the other hand, the present composition may be in the form of a paste or a semi-solid, and the composition preferably has a property of increasing fluidity and rapidly decreasing viscosity upon heating.

When the present composition is used as a hot-melt curable silicone composition, it is preferably a solid that is non-flowing at 25° C., has heat-melting properties, and may be granular or molded into pellet form. The granular composition can be easily obtained by granulating only the individual components that make up the curable silicone composition by mixing them under temperature conditions not exceeding 50° C. The granular curable silicone composition is preferably further molded into a pellet form for use. To make pellets, the sheet-shaped molded body may be die-cut or cut to be molded.

The pellet shape is obtained by compression molding of the present composition, and is excellent in handling workability and curability. The “pellet” may also be referred to as a “tablet”. The shape of the pellet is not limited, but is usually spherical, elliptical spherical, or cylindrical. The size of the pellet is not limited, and for example, the pellet has an average particle diameter or a circle equivalent diameter of 500 pm or more.

The present composition can be handled in the form of pellets at room temperature and is preferably a non-flowable solid at 25° C. Here, the term “non-fluid” means that it is not deformed or flowed in a no-load condition, and it is preferable that it is not deformed or flowed in a no-load condition at 25° C. when it is molded into a pellet, a tablet, or the like. Such non-fluid can be evaluated, for example, by placing a molded product of the composition on a hot plate at 25° C. and substantially not deforming or flowing under no load or constant weight. This is because, when non-fluid at 25° C., shape retention at this temperature is good and the surface tackiness is low.

The softening point of the composition is preferably 100° C. or less. Such a softening point means a temperature at which the deformation amount in the height direction is 1 mm or more when the deformation amount of the composition is measured after the load is removed by continuing to press the hot plate with a load of 100 grams for 10 seconds from above.

The present composition tends to decrease in viscosity rapidly under high temperature and high pressure (that is, in the molding step), and a value measured at a similar high temperature and high pressure is preferably used as a useful melt viscosity value. Therefore, the melt viscosity of the present invention is more preferably measured under high pressure using a Koka-type flow tester (manufactured by the Shimadzu Corporation) than when measured with a rotational viscometer such as a rheometer. Specifically, the present composition should have a melt viscosity at 150° C. of 200 Pa-s or less, and more preferably 150 or less. This is because the adhesiveness to the base material after the composition is hot-melted and then cooled to 25° C. is good.

If the present composition is a hot-melt composition or a granular composition, it can be produced by powder mixing components (A) to (C), as well as any other components, at a temperature of less than 50° C. The powder mixer used in the present manufacturing method is not limited, and exemplified are a uniaxial or biaxial continuous mixer, a two-roll mixer, a ROSS mixer, a Hobart mixer, a dental mixer, a planetary mixer, a kneader mixer, a laboratory mill, a small-sized mill, and a henschel mixer, and preferably, a laboratory mill and a henschel mixer.

The curable silicone composition for transfer molding of the present invention may be in the form of a paste or semi-solid and is preferably a paste or semi-solid composition with limited flowability. The composition can be obtained by uniformly mixing components (A) to (C), as well as any other components, using a mechanical mixer such as a Ross mixer, Hobart mixer, or the like of the mixers described above.

When the present composition is in the form of a paste at 25° C., the viscosity at 25° C. is not particularly limited, but is preferably within the range of 5 to 200 Pa-s, more preferably in the range of 5 to 120 Pa-s, and particularly preferably in the range of 10 to 80 Pa-s. This is because, when the viscosity is greater than or equal to the lower limit of the range described above, the generation of burrs is suppressed during molding of the resulting composition, while when the viscosity is less than or equal to the upper limit of the range described above, the workability of the resulting composition is favorable.

[Method of Molding Cured Product]
The composition can be cured by a method comprising at least the following steps (I) to (III)
(I) a step of heating to a temperature of 100° C. or higher to melt the present composition;
(II) a step of injecting the curable silicone composition obtained in step (I) into a mold or a step of distributing the curable silicone composition obtained in step (I) to a mold by clamping; and
(III) a step of curing the curable silicone composition injected in step (II).

The process described above is applicable to general molding machines such as transfer molding machines, compression molding machines, injection molding machines, auxiliary ram type molding machines, slide type molding machines, double ram type molding machines, or molding machines for low pressure sealing, and the like and these can be suitably used as the composition of the present invention for the purpose of obtaining a cured product by transfer molding.

Finally, in step (III), the curable silicone composition injected (applied) in step (II) is cured. In the case where (c1) organic peroxide is used as component (C), the heating temperature is preferably 150° C. or higher or 170° C. or higher, and in the case where (c2), organohydrogenpolysiloxane having at least two silicon-bonded hydrogen atoms in a molecule and a hydrosilylation reaction catalyst, is used, the heating temperature is preferably 100° C. or higher or 130° C. or higher.

Since it is suitable as a light reflecting material for light emitting/optical devices or as a protective member for semiconductors or the like, the cured product obtained by curing the composition preferably has a Type D Durometer hardness of 20 or more at 25° C. This type-D durometer hardness is determined by the type-D durometer in accordance with the JIS K 6253-1997 “Hardness Testing Methods for Vulcanized Rubber and Thermoplastic Rubber”.

[Use of Composition]

The composition is a material for transfer molding, and is particularly suitable as an encapsulating material for semiconductors and the like using an overmolding method that integrates the substrate and cured product during molding. That is to say, the curable silicone composition for transfer molding of the present invention suitably has hot-melt properties, and has superior workability and curability during melting (hot-melt), and the cured product formed by transfer molding has low modulus and flexibility even at high temperatures, and has superior stress relaxation properties, and thus is suitable for use in semiconductor components such as optical reflective materials for light emitting/optical devices, and the cured product has superior demolding properties after transfer molding and warpage or defects do not readily occur in the molded product during integrated molding. Furthermore, since the cured product has superior mechanical properties, it is suitable as an encapsulant for semiconductors; an encapsulant for power semiconductors such as SiC, GaN, or the like; an adhesive, potting agent, protective agent, and coating agent for electrical and electronic applications. In particular, it is preferable to use the composition as a sealant for semiconductors using an overmold molding method at the time of molding.

[Use of Cured Product]

The application of the cured product of the present invention is not particularly limited as long as the cured product is obtained by transfer molding, but the cured product molded by transfer molding has low modulus and flexibility even at high temperatures, and has superior stress relaxation properties, so that warpage or defects do not readily occur in the molded product. Therefore, the cured product obtained by curing the present composition can be suitably used as a member for a semiconductor device, and can be suitably used as a sealant for a semiconductor element, an IC chip or the like, and as an adhesive/bonding member of a conductor device.

A semiconductor device equipped with a member made of the cured product of the present invention is not particularly limited, but is particularly preferable to be a light emitting semiconductor device which is a light emitting/optical device.

### EXAMPLES

The hot-melt curable silicone composition of the present invention and manufacturing method thereof are described in detail by means of examples and comparative examples. Note that in the formulas, Me, Ph, and Vi represent a methyl group, a phenyl group, and a vinyl group, respectively. The softening point, curing behavior, moldability, and warpage of the molded product of the curable silicone compositions of each example and comparative example were measured by the following methods. The results are shown in Table 1.

[Softening Point of Curable Particulate Silicone Composition]

The curable particulate silicone composition was molded into cylindrical pellets of φ14 mm*22 mm. The pellet was placed on a hot plate set at 25° C. to 100° C. and kept pressed from above for 10 seconds with a load of 100 grams, and after the load was removed, the amount of deformation of the pellet was measured. The temperature at which the deformation amount in the height direction was 1 mm or more was defined as the softening point.

[Curing Behavior of Curable Silicone Compositions]

The curable silicone composition was measured through vulcanization for 600 seconds at the molding temperature (150° C.) using a curastometer (PREMIER MDR manufactured by Alpha Technologies) according to the method specified in JIS K 6300-2:2001, “Unvulcanized rubber—Physical properties—Part 2: Determination of vulcanization characteristics using a vibratory vulcanization tester.” In the case of a hot-melt cured silicone composition, about 7 g was placed on a lower die after molding into cylindrical pellets, and in the case of a liquid cured silicone composition, about 7 g was placed on the lower die as-is, and the measurement started when the upper die was closed. The measurements were made using an R-type die for rubber, with an amplitude angle of 0.53° , a vibration frequency of 100 times/minute, and a maximum torque range of 230 kgf-cm. The stored torque and lost torque were obtained as the measurement results, and the ratio (stored torque/lost torque) was captured as tanδ during curing.

[Properties of Curable Silicone Compositions]

The curable silicone composition was integrally molded with a silver-plated copper lead frame using a transfer molding machine to produce a molded product of 35 mm (length)×25 mm (width)×1 mm (height). Molding conditions were set at 150° C. for the mold temperature and 120 seconds for the mold clamping time, and moldability was checked without applying any release agents to the upper and lower molds of the molding machine. After the molding cycle was complete, the results were confirmed as OK if the integrally molded product could be smoothly demolded from the mold, and NO if it could not be demolded due to sticking to the mold. The demoldability is evaluated under severe conditions by using silver, a difficult-to-bond material, as the adherend.

[Warpage of Molded Products]

The cured silicone composition was integrally molded on an aluminum plate of size 60 mm×60 mm×0.4 mm by heating at 150° C. for 2 hours using a heat press with a size of 60 mm×60 mm×0.6 mm. One side of the obtained molded product was fixed to a horizontal desk with tape and the lift distance of the other side from the desk was measured using a ruler to determine the warpage value of the molded product.

Organopolysiloxane resins or organopolysiloxane crosslinked products containing a hydrosilylation reaction catalyst were prepared by the methods shown in Reference Examples 1 to 6 below, and their hot melt properties were evaluated by the presence or absence of softening point/melt viscosity. The organopolysiloxane resin microparticles were also prepared by the method shown in Reference Examples 3 to 6. In the reference examples, the 1,1,3,3-tetramethyl-1,3-divinyl disiloxane used for the platinum complex that is the hydrosilylation reaction catalyst is described as “1,3-divinyltetramethyldisiloxane”.

### Reference Example 1

A toluene solution of a resinous organopolysiloxane (1) containing 10 ppm of platinum metal in mass units was prepared by charging 270.5 g of a 55 mass % toluene solution of a resinous organopolysiloxane represented by the average unit formula:

(PhSiO_{3/2})_{0.80}(Me₂ViSiO_{1/2})_{0.20,}

which is a white solid at 25° C., 21.3 g of a diphenylsiloxane capped at both molecular terminals with dimethylhydrogensiloxy groups and having a viscosity of 5 mPa·s (silicon-bonded hydrogen atom content=0.6 mass %) represented by the formula:

HMe₂SiO(Ph₂SiO)SiMe₂H,

(in an amount such that the amount of silicon-bonded hydrogen atoms in this component is 0.5 mol relative to 1 mol of vinyl groups in the resinous organopolysiloxane), and 0.43 g of a 1,3-divinyltetramethyldisiloxane solution of platinum 1,3-divinyltetramethyldisiloxane complex (platinum metal content=approximately 4000 ppm) (in an amount such that the amount of platinum metal is 10 ppm in mass units with respect to this liquid mixture) into a 1 L flask and stirring uniformly at room temperature. Thereafter, the temperature in the flask was raised to 100° C. by an oil bath, and the mixture was stirred under a reflux of toluene for 2 hours to prepare a toluene solution of an organosiloxane crosslinked product (1) containing a resinous organosiloxane derived from the above-mentioned resinous organopolysiloxane and a chained organosiloxane derived from the above-mentioned diphenylsiloxane and having a vinyl group not involved in the above-mentioned reaction. When the organosiloxane crosslinked product (1) was analyzed by FT-IR, peaks of silicon-bonded hydrogen atoms were not observed. In addition, the softening point of this organosiloxane crosslinked product (1) was 75° C., and the melt viscosity thereof at 100° C. was 700 Pa-s.

### Reference Example 2

An Organopolysiloxane 55 mass % xylene solution 270.5 g as well as platinum 1,3-divinyltetramethyldisiloxane complex 1,3-divinyltetramethyldisiloxane solution (platinum metal content=approximately 4,000 ppm) 0.375 g expressed by the average unit formula: (Me₂ViSiO_{1/2})0.05(Me₃SiO_{1/2})_{0.39}(SiO_{4/2})_{0.56}(HO_{1/2})_{0.02} was introduced into a 1 L flask in white solid form at 25° C. and was uniformly stirred at room temperature (25° C.) to prepare an organopolysiloxane resin (2) xylene solution containing 10 ppm in terms of mass units as platinum metal. In addition, the organopolysiloxane resin (2) did not soften/melt even when heated to 200° C. and did not have hot-melt properties.

### Reference Example 3

An organopolysiloxane 55 mass % xylene solution 270.5 g as well as platinum 1,3-divinyltetramethyldisiloxane complex 1,3-divinyltetramethyldisiloxane solution (platinum metal content=approximately 4,000 ppm) 0.375 g expressed by the average unit formula: (Me₃SiO_{1/2})_{0.44} (SiO_{4/2})_{0.56}(HO_{1/2})_{0.02} was introduced into a 1 L flask in white solid form at 25° C. and was uniformly stirred at room temperature (25° C.) to prepare an organopolysiloxane resin (3) xylene solution containing 10 ppm in terms of mass units as platinum metal. In addition, the organopolysiloxane resin (3) did not soften/melt even when heated to 200° C. and did not have hot-melt properties.

### Reference Example 4: Hot-Melt Organopolysiloxane Resin Particles (1)

True-spherical hot-melt silicone microparticles (1) were prepared by atomizing the toluene solution of the organosiloxane crosslinked product (1) prepared in Reference Example 1 by spray drying at 40° C. while removing toluene. Observation of the fine particles with an optical microscope revealed that the particle diameter was 5 to 10 μm and the average particle diameter was 7.5 μm.

### Reference Example 5: Hot-Melt Organopolysiloxane Resin Particles (2)

A xylene solution of the organopolysiloxane resin (2) prepared in Reference Example 1 was converted into particles while removing the xylene by a spray method using a spray dryer at 50° C. Thus, spherical, non-hot melt organopolysiloxane resin particles (2) were prepared. Observation of the microparticles with an optical microscope revealed that the particle diameter was 5 to 10 μm and the average particle diameter was 6.9 μm.

### Reference Example 6: Hot-Melt Organopolysiloxane Resin Particles (3)

A xylene solution of the organopolysiloxane resin (3) prepared in Reference Example 2 was converted into particles while removing the xylene by a spray method using a spray dryer at 50° C. Thus, spherical, non-hot melt organopolysiloxane resin particles (3) were prepared. Observation of the microparticles with an optical microscope revealed that the particle diameter was 5 to 10 μm and the average particle diameter was 7.4 μm.

### Example 1

73.1 g of hot-melt silicone microparticles (1), 9.5 g of diphenylsiloxane capped at both molecular terminals with dimethylhydrogensiloxy groups and which has a viscosity of 5 mPa-s, represented by the formula: HMe₂SiO(Ph₂SiO)SiMe₂H (content of silicon-bonded hydrogen atoms=0.6 mass %), 17.4 g of methylphenylpolysiloxane capped at both molecular terminals with dimethylvinylsiloxy groups and which has a viscosity of 1,000 mPa-s represented by the average formula: Me₂ViSiO(MePhSiO)_{17.5}SiMe₂Vi (content of vinyl groups=2.1 mass %) {at an amount such that the amount of silicon-bonded hydrogen atoms in the diphenylsiloxane is 0.9 mol with regards to 1 mol of vinyl groups in the silicone microparticles (1) and methylphenylpolysiloxane capped at both molecular terminals with dimethylvinylsiloxy groups}, 1-ethynyl-1-cyclohexanol (at an amount of 300 ppm in terms of mass units with regard to the present composition), 24.0 g of a fused silica having an average particle diameter of 2.5 μm (SP60 manufactured by Nippon Steel Materials Micron Co.), and 30.0 g of fumed silica having an average particle diameter of 0.04 μm (AEROSIL50 from Japan Aerosil) were all together introduced into a small grinder, and stirring was performed for 1 minute at room temperature (25° C.) to prepare a uniform curable granular silicone composition. The measurement results of the softening point and other properties of this composition are shown in Table 1.

### Example 2

89.3 g of hot-melt silicone microparticles (1), 10.7 g of diphenylsiloxane capped at both molecular terminals with dimethylhydrogensiloxy groups and which has a viscosity of 5 mPa-s, represented by the formula: HMe₂SiO(Ph₂SiO)SiMe₂H (content of silicon-bonded hydrogen atoms=0.6 mass %), {at an amount such that the amount of silicon-bonded hydrogen atoms in the diphenylsiloxane is 0.9 mol with regards to 1 mol of the vinyl groups in the silicone microparticles (1)}, 1-ethynyl-1-cyclohexanol (at an amount of 300 ppm in terms of mass units with regard to the present composition), 98.0 g of titanium oxide having an average particle diameter of 0.5 μm (SX-3103 manufactured by Sakai Chemical Industry Co., Ltd.), and 4.0 g of fumed silica having an average particle diameter of 0.04 μm (AEROSIL50 from Japan Aerosil) were all together introduced into a small grinder, and stirring was performed for 1 minute at room temperature (25° C.) to prepare a uniform curable granular silicone composition. The measurement results of the softening point and other properties of this composition are shown in Table 1.

### Example 3

64.1 g of Methyl vinyl phenyl polysiloxane represented by the average unit formula: (MeViSiO_{2/2})_{0.25}(PhSiO_{3/2})_{0.75} with a viscosity of 1,000 mPa-s, 10.5 g of methylphenylpolysiloxane capped at both molecular terminals with dimethylvinylsiloxy groups with the average formula Me₂ViSiO(MePhSiO)_{17.5}SiMe₂Vi (vinyl group content=2.1 mass %) 1.0 g of 1,3,5,7-tetramethyl-1,3,5,7-tetravinylcyclotetrasiloxane represented by formula (MeViSiO)₄; 22.2 g of 1,1,5,5-tetramethyl-3,3-diphenyltrisiloxane represented by formula (HMe₂SiO)₂SiPh₂; 2.3 g of Methylphenylpolysiloxane containing silicon-bonded hydrogen atoms represented by (Me₂HSiO_{1/2})_{0.6}(PhSiO_{3/2})_{0.4} {the amount of SiH groups in the silicon-bonded hydrogen atom containing polysiloxane is 0.93 mol relative to a total of 1 mole of vinyl groups in the vinyl group containing polysiloxane} platinum 1,3-divinyl-1,1,3,3-tetramethyldisiloxane 1,3-divinyl-1,1,3,3-tetramethyldisiloxane solution (amount of platinum metal set to 3.5 ppm by mass for this composition), 1-ethynyl-1-cyclohexanol (amount to be 200 ppm by mass unit for this composition), 25 g of titanium dioxide (SX-3103 manufactured by Sakai Chemical Industry Co., Ltd.) with an average primary particle diameter of 0.2 μm were uniformly mixed by mechanical force (Hobart mixer) to prepare a curable silicone composition which is in the form of a paste at room temperature. The measurement results of the characteristic values of this composition are shown in Table 1. Since the composition is in paste form, the softening point was not been measured (N/A).

### Example 4

57.3 g of Methyl vinyl phenyl polysiloxane, represented by the average unit formula: (MeViSiO_{2/2})_{0.25}(PhSiO_{3/2})_{0.75}; 5.0 g of methylvinylphenylpolysiloxane represented by (MeViSiO_{2/2})_{0.68}(PhSiO_{3/2})_{0.32}; 9.0 g of methylphenylpolysiloxane capped at both molecular terminals with dimethylvinylsiloxy groups with the average formula Me₂ViSiO(MePhSiO)_{17.5}SiMe₂Vi with a viscosity of 1,000 mPa-s (vinyl group content=2.1 mass %); 1.1 g of 1,3,5,7-tetramethyl-1,3,5,7-tetravinylcyclotetrasiloxane represented by (MeViSiO)₄; 24.4 g of 1,1,5,5-tetramethyl-3,3-diphenyltrisiloxane represented by (HMe₂SiO)₂SiPh₂; 3.2 g of Methylphenylpolysiloxane containing silicon-bonded hydrogen atoms represented by (Me₂HSiO_{1/2})_{0.6}(PhSiO_{3/2})_{0.4}; {the amount of SiH groups in the silicon-bonded hydrogen atoms containing polysiloxane is 0.97 mol relative to a total of 1 mol of vinyl groups in the vinyl group containing polysiloxane} platinum 1,3-divinyl-1,1,3,3-tetramethyldisiloxane 1,3-divinyl-1,1,3,3-tetramethyldisiloxane solution (amount of platinum metal set to 3.5 ppm by mass for this composition), 1-ethynyl-1-cyclohexanol (amount to be 200 ppm by mass unit for this composition); 43 g of titanium dioxide (SX-3103 manufactured by Sakai Chemical Industry Co., Ltd.) with an average primary particle diameter of 0.2 μm were uniformly mixed by mechanical force (Hobart mixer) to prepare a curable silicone composition which is in the form of a paste at room temperature. The measurement results of the characteristic values of this composition are shown in Table 1. Since the composition is in paste form, the softening point was not been measured (N/A).

### Comparative Example 1

55.3 g of (a+c(pt)) non-hot meltable organopolysiloxane resin microparticles (3) (vinyl group content=0 mass %), 13.8 g of (a+c(pt)) non-hot meltable organopolysiloxane resin microparticles (2) (vinyl group content=1.91 mass %), (b1) 29.6 g of dimethylpolysiloxane capped at both molecular terminals with dimethylvinylsiloxy groups represented by the Formula: ViMe₂SiO(Me₂SiO)₈₀₀SiViMe₂ (vinyl group content=0.09 mass %), 1.1 g of organohydrogenpolysiloxane resin represented by (c2(SiH)) Formula: (HMe₂SiO_{1/2})_{0.67}(SiO_{4/2})_{0.33} (content of silicon-bonded hydrogen atoms=0.95 mass %) {amount of silicon-bonded hydrogen atoms in the organohydrogenpolysiloxane resin set to 1.1 moles for 1 mole of vinyl groups in the organopolysiloxane resin granular particles (2) and the dimethylpolysiloxane capped at both molecular terminals with dimethylvinylsiloxy groups}, (d1) 232.6 g of alumina (AES-12 from Sumitomo Chemical) having an average particle diameter of 0.44 μm, 1-ethynyl-1-cyclohexanol (amount to be 1,000 ppm in mass units for this composition) was introduced all at once into a small grinder and stirred for 1 minute at room temperature (25° C.) to prepare a uniform curable granular silicone composition. The measurement results of the softening point and other properties of this composition are shown in Table 1.

### Comparative Example 2

89.3 g of hot-melt silicone microparticles (1), 10.7 g of diphenylsiloxane capped at both molecular terminals with dimethylhydrogensiloxy groups and which has a viscosity of 5 mPa-s, represented by the formula: HMe₂SiO(Ph₂SiO)SiMe₂H (content of silicon-bonded hydrogen atoms=0.6 mass %), {at an amount such that the amount of silicon-bonded hydrogen atoms in the diphenylsiloxane is 0.9 mol with regards to 1 mol of the vinyl groups in the silicone microparticles (1)}, 1-ethynyl-1-cyclohexanol (at an amount of 300 ppm in terms of mass units with regard to the present composition), 298.5 g of titanium dioxide having an average particle diameter of 0.5 μm (SX-3103 manufactured by Sakai Chemical Industry Co., Ltd.), and 1.5 g of fumed silica having an average particle diameter of 0.04 μm (AEROSIL50 from Japan Aerosil) were all together introduced into a small grinder, and stirring was performed for 1 minute at room temperature (25° C.) to prepare a uniform curable granular silicone composition. The measurement results of the softening point and other properties of this composition are shown in Table 1.

### Comparative Example 3

45.0 g of hot-melt silicone particles (1), 47.6 g of methylphenylpolysiloxane capped at both molecular terminals with dimethylvinylsiloxy groups represented by the average formula Me₂ViSiO(MePhSiO)₉₂SiMe₂Vi with viscosity of 20,000 mPa-s (vinyl group content=0.63 mass %); 1.0 g of diphenylsiloxane capped at both molecular terminals with dimethylvinylsiloxy groups with viscosity of 5 mPa-s, represented by the formula HMe₂SiO(Ph₂SiO)SiMe₂H (silicon-bonded hydrogen atom content=0.6 mass %); 6.3 g branched-chain organopolysiloxane having a viscosity of 25 mPa-s and having two or more silicon-bonded hydrogen atoms in one molecule represented by an average unit formula: (PhSiO_{3/2})_{0.4}(HMe₂SiO_{1/2})_{0.6}, (silicon-bonded hydrogen atom content=0.65 mass %); {an amount such that the amount of silicon-bonded hydrogen atoms in the diphenylsiloxane and branched chain organopolysiloxane is 1.0 mol relative to 1.0 mol of vinyl groups in the silicone microparticles (1)}, 1-ethynyl-1-cyclohexanol (at an amount of 300 ppm in terms of mass units for the present composition), 98.0 g of titanium dioxide (SX-3103 manufactured by Sakai Chemical Industry Co., Ltd.) with an average particle diameter of 0.5 μm; 4.0 g of fumed silica (AEROSIL 50 manufactured by AEROSIL Japan) having an average particle diameter of 0.04 μm, were all introduced together into a small grinder, and stirred for 1 minute at room temperature (25° C.) to prepare a uniform curable granular silicone composition. The measurement results of the softening point and other properties of this composition are shown in Table 1.

### Comparative Example 4

(a+c(pt)) 34.1 g of non-hot meltable organopolysiloxane resin microparticles (2) (vinyl group content=0 mass %); (a+c(pt)) 34.1 g of non-hot meltable organopolysiloxane resin microparticles (1) (vinyl group content=1.91 mass %); (b2) 14.5 g of dimethylpolysiloxane capped at both molecular terminals with dimethylvinylsiloxy groups represented by the formula: ViMe₂SiO(Me₂SiO)₁₄₀SiViMe₂ (vinyl group content=0.44 mass %); (b3) 14.5 g of dimethylpolysiloxane capped at both molecular terminals with dimethylvinylsiloxy groups represented by the formula: ViMe₂SiO(Me₂SiO)₃₀₀SiViMe₂ (vinyl group content=0.21 mass %); (c2(SiH)) 2.85 g of organohydrogenpolysiloxane resin represented by the formula: (HMe₂SiO_{1/2})_{0.67}(SiO_{4/2})_{0.33} (silicon-bonded hydrogen atom content=0.95 mass %); {amount such that the silicon-bonded hydrogen atom in the organohydrogenpolysiloxane resin is 1.1 mol relative to 1 mol of vinyl groups in the organopolysiloxane resin microparticle granules (1) and dimethylpolysiloxane capped at both molecular terminals with dimethylvinylsiloxy groups}; (d2) 142.6 g of titanium dioxide (SX-3103 manufactured by Sakai Chemical Industry Co., Ltd.) having an average particle diameter of 0.5 pm; (d3) 10.3 g of fumed silica (AEROSIL 50 from Japan Aerosil) having an average particle diameter of 0.04 μm; and 1-ethynyl-1-cyclohexanol (amount to be 1,000 ppm in mass units for this composition), were all together introduced into a small grinder, and stirring was performed for 1 minute at room temperature (25° C.) to prepare a uniform curable granular silicone composition. The measurement results of the softening point and other properties of this composition are shown in Table 1.

### Comparative Example 5

(a+c(pt)) 41.3 g of non-hot meltable organopolysiloxane resin microparticles (2) (vinyl group content=0 mass %), (a+c(pt)) 27.5 g of non-hot meltable organopolysiloxane resin microparticles (1) (vinyl group content=1.91 mass %), (b4) 27.5 g of dimethylpolysiloxane capped at both molecular terminals with dimethylvinylsiloxy groups represented by the formula: ViMe₂SiO(Me₂SiO)₄₅SiViMe₂ (vinyl group content=1.53 mass %); (c2(SiH)) 3.68 g of organohydrogenpolysiloxane resin represented by the formula: (HMe₂SiO_{1/2})_{0.67}(SiO_{4/2})_{0.33} (silicon-bonded hydrogen atom content=0.95 mass %);

{amount such that the silicon-bonded hydrogen atom in the organohydrogenpolysiloxane resin is 1.0 mol relative to 1 mol of vinyl groups in the organopolysiloxane resin microparticle granules (1) and dimethylpolysiloxane capped at both molecular terminals with dimethylvinylsiloxy groups}; (d2) 299.0 g of titanium dioxide (SX-3103 manufactured by Sakai Chemical Industry Co., Ltd.) having an average particle diameter of 0.5 μm; (d3) 1.5 g of fumed silica (AEROSIL 50 from Japan Aerosil) having an average particle diameter of 0.04 μm; and 1-ethynyl-1-cyclohexanol (amount to be 1,000 ppm in mass units for this composition), were all together introduced into a small grinder, and stirring was performed for 1 minute at room temperature (25° C.) to prepare a uniform curable granular silicone composition. The measurement results of the softening point and other properties of this composition are shown in Table 1.

### Comparative Example 6

55.2 g of methylvinylphenylpolysiloxane represented by the average unit formula: (MeViSiO_{2/2})_{0.15}(Me₂SiO_{2/2})_{0.15}(Ph₂SiO_{2/2})_{0.30}(PhSiO_{3/2})_{0.40}(HO_{1/2})_{0.04}; 13.8 g of 1,3,5,7-tetramethyl-1,3,5,7-tetravinylcyclotetrasiloxane represented by the formula: (MeViSiO)₄; 30.9 g of 1,1,5,5-tetramethyl-3,3-diphenyltrisiloxane represented by the formula: (HMe₂SiO)₂SiPh₂ (an amount such that the silicon-bonded hydrogen atoms in the molecule is 0.9 mol relative to 1 mol of the total vinyl groups in the methylvinylphenylpolysiloxane and 1,3,5,7-tetramethyl-1,3,5,7-tetravinylcyclotetrasiloxane); a 1,3-divinyl-1,1,3,3-tetramethyldisiloxane platinum 1,3-divinyl-1,1,3,3-tetramethyldisiloxane solution (an amount where platinum metal is 3.5 ppm in terms of mass units with respect to this composition); 1-ethynyl-1-cyclohexanol (amount to be 200 ppm in mass units for this composition); 55.2 g of titanium dioxide (SX-3103 manufactured by Sakai Chemical Industry Co., Ltd.) having an average particle diameter of 0.2 μm; 74.6 g of crushed quartz powder with an average particle diameter of 5 μm (Crystalite VX-52 manufactured by Tatsumori Ltd.); and 60.8 g of spherical silica with an average particle diameter of 15 μm (HS-202 manufactured by Nippon Steel Materials Micron), were mixed together to prepare a curable silicone composition in paste form. The measurement results of the softening point and other properties of this composition are shown in Table 1.

### Comparative Example 7

89.3 g of hot-melt silicone particles (1); 5.35 g of diphenylsiloxane capped at both molecular terminals with dimethylhydrogensiloxy groups with a viscosity of 5 mPa-s represented by the formula: HMe₂SIO(Ph₂SiO)SiMe₂H (content of silicon-bonded hydrogen atoms=0.6 mass %); 5.35 g of branched chain organopolysiloxane with at least 2 or more silicon-bonded hydrogen atoms in the molecule having a viscosity of 25 mPa-s represented by the average unit formula: (PhSiO_{3/2})_{0.4}(HMe₂SIO_{1/2})_{0.6;} (content of silicon-bonded hydrogen atoms=0.65 mass %); {an amount such that the silicon-bonded hydrogen atoms in the diphenylsiloxane and branched chain organopolysiloxane is 1.0 mol relative to 1 mol of vinyl groups in the silicone microparticles (1)}; 1-ethynyl-1-cyclohexanol (amount to be 300 ppm in mass units for this composition); and 402 g of spherical silica with an average particle diameter of 15 pm (HS-202 manufactured by Nippon Steel Materials Micron); were all together introduced into a small grinder, and stirring was performed for 1 minute at room temperature (25° C.) to prepare a uniform curable granular silicone composition. The measurement results of the softening point and other properties of this composition are shown in Table 1.

TABLE 1

| | | | | | Comparative | Comparative |
|---|---|---|---|---|---|---|
| | Example | Example | Example | Example | Example | Example |
| Experiment example | 1 | 2 | 3 | 4 | 1 | 2 |
| Properties of curable | | | | | | |
| silicone compositions | | | | | | |
| Softening point | 60 | 60 | N/A | N/A | 80 | 75 |
| (° C.) | | | | | | |
| MDR | 12 | 17 | 36 | 25 | 6 | 34 |
| measurement: | | | | | | |
| Maximum torque | | | | | | |
| [dNm] | | | | | | |
| MDR | 0.16 | 0.12 | 0.03 | 0.10 | 0.54 | 0.06 |
| measurement: | | | | | | |
| tanδ at maximum | | | | | | |
| torque | | | | | | |
| Formability | OK | OK | OK | OK | NO | OK |
| Properties of Cured | | | | | | |
| Product | | | | | | |
| Warpage of | 0 | 0 | 0 | 0 | 0 | 5 |
| molded product [mm] | | | | | | |

| | Comparative | Comparative | Comparative | Comparative | Comparative |
|---|---|---|---|---|---|
| | Example | Example | Example | Example | Example |
| | 3 | 4 | 5 | 6 | 7 |
| Properties of curable | | | | | |
| silicone compositions | | | | | |
| Softening point | 65 | 90 | 100 | N/A | 65 |
| (° C.) | | | | | |
| MDR | 45 | 41 | 64 | 132 | 194 |
| measurement: | | | | | |
| Maximum torque | | | | | |
| [dNm] | | | | | |
| MDR | 0.34 | 0.51 | 0.31 | 0.25 | 0.11 |
| measurement: | | | | | |
| tanδ at maximum | | | | | |
| torque | | | | | |
| Formability | NO | NO | OK | OK | OK |
| Properties of Cured | | | | | |
| Product | | | | | |
| Warpage of | 3 | 1 | 3 | 6 | 5 |
| molded product [mm] | | | | | |

[Summary]

The curable silicone composition of Examples 1 to 4 (hot-melt Examples 1 and 2, and paste-type Examples 3 and 4) of the present invention satisfy the curing behavior (maximum torque value and loss tangent (tanδ) value) measured by the MDR specified in the present invention, and moldability is good and the molded articles can be smoothly separated from the mold, and no warpage of the molded product occurs, which confirms that it has superior stress relaxation properties.

On the other hand, Comparative Examples 1 to 7 did not satisfy the curing behavior measured by MDR specified in the present invention, and there was a trade-off relationship between the moldability and the suppression of warpage of the molded product (=low warpage), and these could not be achieved at the same time.

1. A curable silicone composition for transfer molding, wherein:
(1) the maximum torque measured from a molding temperature of room temperature through 200° C. using a moving die rheometer (MDR) is less than 50 dN-m; and
(2) the loss tangent (tanδ) expressed by the ratio of stored torque value/lost torque value is less than 0.2.

2. The curable silicone composition for transfer molding according to claim comprising:
(A) a curable reactive organopolysiloxane;
(B) a functional filler; and
(C) a curing agent;
wherein 50 mass % or more of component (A) is (A1) an organopolysiloxane having at least one curable reactive functional group containing a carbon-carbon double bond in the molecule and where 20 mol % or more of the total siloxane units of the organopolysiloxane is siloxane units represented by RSiO_{3/2} or SiO_{4/2} where R is a monovalent organic group; and or more of the total siloxane units, and
wherein the content of component (B) is 40 volume % or less of the entire composition.

3. The curable silicone composition for transfer molding according to claim 1, wherein the entire composition has hot melt properties.

4. The curable silicone composition for transfer molding according to claim 2, wherein component (A) is (A1-1) a hot-meltable organopolysiloxane microparticle having hydrosilylated reactive groups and/or radical reactive groups.

5. The curable silicone composition for transfer molding according to claim 2, wherein component (A) is an organopolysiloxane microparticle comprising:
(A₁) a resinous organopolysiloxane;
(A₂) an organopolysiloxane crosslinked product comprising at least one partially crosslinked organopolysiloxane; and
(A₃) a block copolymer comprising a resinous organosiloxane block and a chain organosiloxane block,
or a mixture of at least two of these.

6. The curable silicone composition for transfer molding according to claim 2, wherein component (A) is organopolysiloxane microparticles containing a siloxane unit represented by R^{A}SiO_{3/2} where R^{A} is an aryl group having 6 to 20 carbon atoms.

7. The curable silicone composition for transfer molding according to claim 2, wherein component (B) is one or more types selected from the group consisting of a reinforcing filler, a white pigment, a thermally conductive filler, an electrically conductive filler, and an organic filler.

8. The curable silicone composition for transfer molding according to claim 1, wherein the composition is in pellet form.

9. A cured product obtained by curing the curable silicone composition for transfer molding according to claim 1.

10. A member for a semiconductor device, the member comprising the cured product according to claim 9.

11. A semiconductor device comprising the cured product according to claim 9.

12. The semiconductor device of claim 11, wherein the semiconductor device is selected from the group consisting of a power semiconductor device, an optical semiconductor device, and a semiconductor device mounted on a flexible circuit board.

13. A method for manufacturing the curable silicone composition for transfer molding according to claim 2, wherein each component that makes up the curable silicone composition is granulated by mixing under temperature conditions not exceeding 50° C.

14. A method of molding a cured product comprising the following steps:
(I) heating and melting the curable silicone composition for transfer molding according to claim 1 at a temperature of 50° C. or higher;
(II) injecting the curable silicone composition in a liquid state obtained in step (I) into a mold or distributing the curable silicone composition obtained in step (I) to a mold by clamping; and
(III) curing the curable silicone composition injected or distributed in step (II).

15. The method for molding a cured product, comprising a coating process for overmolding and underfilling a semiconductor device using a cured product formed from the curable silicone composition for transfer molding according to claim 1.

16. The method for molding a cured product according to claim 15, comprising:
covering a surface of a semiconductor wafer substrate on which a single or plurality of semiconductor devices are mounted with a cured product formed from the curable silicone composition; and
overmolding the semiconductor wafer substrate so that a gap between the semiconductor devices is filled with the cured product.
